(19) United States
(12) Patent Application Publication
(10) Pub. No.: US 2026/0101480 A1
(43) Pub. Date: Apr. 9, 2026

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Kazuhiko Tsuchiya, Kakegawa-shi (JP)

(21) Appl. No.: 19/347,770

(22) Filed: Oct. 2, 2025

(30) Foreign Application Priority Data
Oct. 7, 2024 (JP) 2024-175931

(51) Int. Cl. H05K 7/20

(52) U.S. Cl. CPC H05K 7/2039

(57) ABSTRACT

An electrical connection unit includes a heat dissipation member, a first electronic component, a first base member, a first bus bar, a second electronic component, a second base member, a second bus bar, and a heat transfer portion. The heat dissipation member includes a first region and a second region. The first electronic component faces the first region in a first direction. The first base member faces the first region in the first direction. The first bus bar is supported by the first base member. The second electronic component faces the second region in the first direction, and has a smaller amount of heat generation than the first electronic component. The second base member faces the second region in the first direction and has an insulating property. The second bus bar is supported by the second base member. The heat transfer portion extends over the first region and the second region when viewed from the first direction.

### TECHNICAL FIELD

Embodiments of the present invention relate to an electrical connection unit.

Priority is claimed on Japanese Patent Application No. 2024-175931 filed in Japan on Oct. 7, 2024, the content of which is incorporated herein by reference.

### BACKGROUND ART

An electrical connection unit having an electronic component and a bus bar electrically connected to the electronic component is known.

### PRIOR ART DOCUMENT

### Patent Document

[Patent Document 1] Japanese Unexamined Patent Application, First Publication No. 2024-037492

### SUMMARY OF THE INVENTION

### Problems to be Solved by the Invention

Incidentally, it is expected to improve a heat dissipation property of an electrical connection unit.

An embodiment provides an electrical connection unit capable of improving a heat dissipation property.

### Means for Solving the Problem

An electrical connection unit according to an embodiment includes a heat dissipation member, a first electronic component, a first base member, a first bus bar, a second electronic component, a second base member, a second bus bar, and a heat transfer portion. The heat dissipation member includes a first region and a second region. The first electronic component faces the first region in a first direction. The first base member faces the first region in the first direction and has an insulating property. The first bus bar is supported by the first base member and electrically connected to the first electronic component. The second electronic component faces the second region in the first direction, and has a smaller amount of heat generation than the first electronic component. The second base member faces the second region in the first direction and has an insulating property. The second bus bar is supported by the second base member and electrically connected to the second electronic component. The heat transfer portion extends over the first region and the second region when viewed from the first direction.

### Effects of Invention

According to one embodiment, it is possible to improve a heat dissipation property.

### BRIEF DESCRIPTION OF THE DRAWINGS

FIG. 1 A cross-sectional view illustrating an electrical connection unit of an embodiment.

FIG. 2 A perspective view for describing a main body of the embodiment.

FIG. 3 A perspective view for describing one subunit of the embodiment.

FIG. 4 A perspective view illustrating an electronic component and a connection component of the embodiment.

FIG. 5 A perspective view for describing a routing board of the embodiment.

FIG. 6 A partially exploded perspective view of the routing board of the embodiment.

FIG. 7 A plan view illustrating a subunit of the embodiment.

FIG. 8 A cross-sectional view taken along line F8-F8 of a structure illustrated in FIG. 7.

FIG. 9 A cross-sectional view taken along line F9-F9 of the structure illustrated in FIG. 7.

FIG. 10 A perspective view illustrating another subunit of the embodiment.

FIG. 11 A front view illustrating an electronic component of an embodiment.

FIG. 12 A perspective view illustrating a base member of the embodiment.

FIG. 13 A plan view illustrating a subunit of the embodiment.

FIG. 14 A cross-sectional view taken along line F14-F14 of a structure illustrated in FIG. 13.

FIG. 15 A cross-sectional view taken along line F15-F15 of the structure illustrated in FIG. 13.

FIG. 16 A cross-sectional view taken along line F16-F16 of the structure illustrated in FIG. 13.

FIG. 17 A perspective view illustrating a coupling structure between a plurality of subunits of the embodiment.

FIG. 18 A cross-sectional view taken along line F18-F18 of a structure illustrated in FIG. 13.

FIG. 19 A perspective view for describing an electrical connection unit of a first modification example of the embodiment.

FIG. 20 A perspective view for describing an electrical connection unit of a second modification example of the embodiment.

FIG. 21 A cross-sectional view for describing the electrical connection unit of the second modification example of the embodiment.

### EMBODIMENTS FOR CARRYING OUT THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

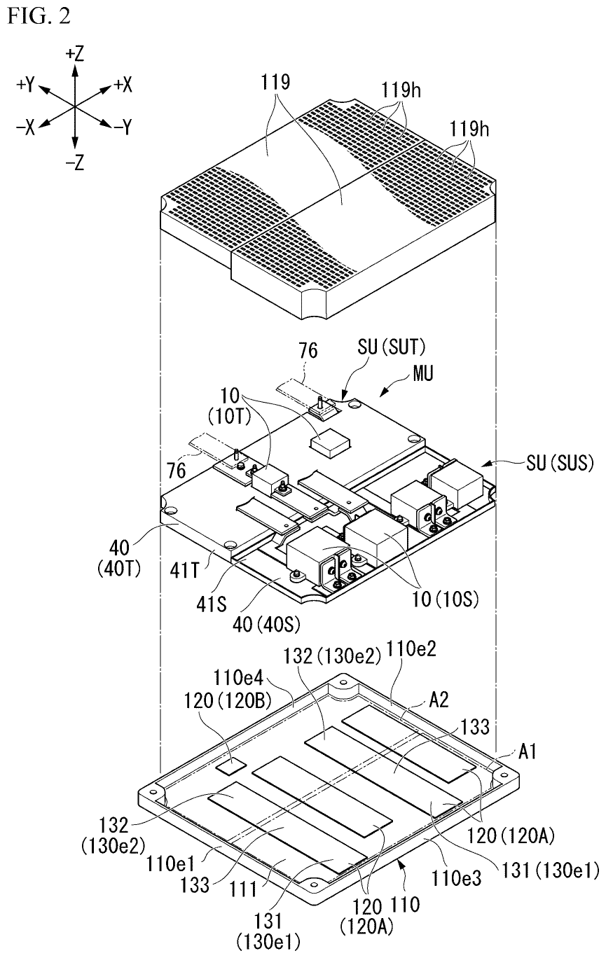

In the present disclosure, a +X direction, a −X direction, a +Y direction, a −Y direction, a +Z direction, and a −Z direction are defined as follows. The +X direction is a direction from a first end 110e1 to a second end 110e2 of a metal plate 110 that will be described later (see FIG. 2). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 110e3 to a fourth end 110e4 of the metal plate 110 that will be described later (see FIG. 2). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 110 that will be described later toward a main body MU (see FIG. 2). The −Z direction is a direction opposite to the +Z direction. Hereinafter, in a case where the +Z direction and the −Z direction are not distinguished, the directions will be simply referred to as “Z direction”. The Z direction is an example of a “first direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### Embodiment

### 1. Constitution of Electrical Connection Unit

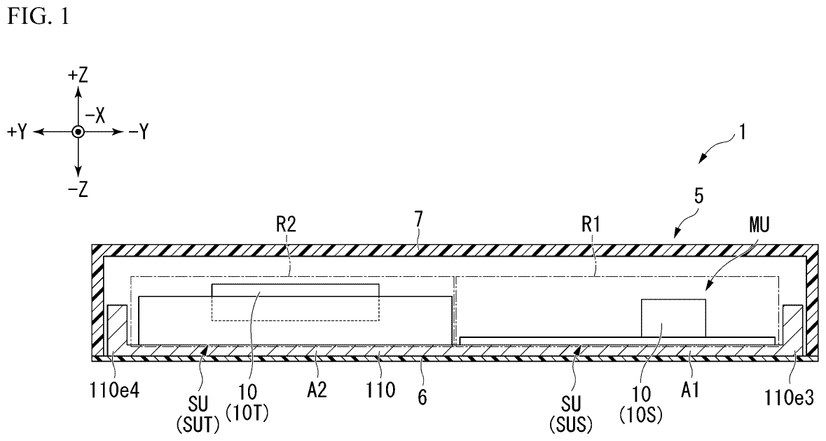

FIG. 1 is a cross-sectional view illustrating an electrical connection unit 1 of an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a casing 5, a main body MU, a metal plate 110, a plurality of insulating covers 119 (see FIG. 2), and a plurality of heat transfer members 120 (see FIG. 2).

### 2. Casing

First, the casing 5 will be described. The casing 5 forms an outline of the electrical connection unit 1. The casing 5 includes, for example, a base 6 (first member) and a cover 7 (second member). The base 6 is a member that covers the main body MU and the metal plate 110 from below. The base 6 has, for example, a plate shape formed in the horizontal direction or a bowl shape open in the +Z direction. The base 6 is made of, for example, a synthetic resin. The cover 7 is a member that covers the main body MU and the metal plate 110 from above. The base 6 has, for example, a bowl shape open in the −Z direction. The cover 7 is made of, for example, a synthetic resin. In the present embodiment, the box-shaped casing 5 is formed by combining the base 6 and the cover 7. The shape of the casing 5 is not limited to the above example. For example, the metal plate 110 that will be described later may function as a part or the whole of the base 6. The casing 5 may be omitted.

In the present embodiment, the electrical connection unit 1 includes a first region (first space) R1 and a second region (second space) R2. The first region R1 is a region in which a heat dissipation property is emphasized. In the first region R1, for example, an electronic component 10S having a great amount of heat generation is disposed. The electronic component 10S is an example of a “first electronic component”. On the other hand, the second region R2 is a region in which a mountability is emphasized. In the second region R2, for example, an electronic component 10T that has a smaller amount of heat generation than the electronic component 10S and/or requires a more complicated mounting structure than the electronic component 10S is disposed. The electronic component 10T is an example of a “second electronic component”. However, these contents do not limit the contents of the electrical connection unit 1 of the present disclosure.

### 3. Main Body

Next, the main body MU will be described.

FIG. 2 is a perspective view for describing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting the plurality of subunits SU, for example. In the present embodiment, the main body MU includes two subunits SU (subunit SUS and SUT). Each subunit SU may be referred to as a “circuit constitution body”.

The subunit SUS has an electrical first function. The subunit SUS includes, for example, a plurality of electronic components 10S and a routing board 40S. The plurality of electronic components 10S are electrically connected to the routing board 40S. The base plate 41S (that will be described later) included in the subunit SUS is an example of a “first base member”.

The subunit SUT has an electrical second function. The second function is, for example, a function different from the first function. The subunit SUT includes, for example, a plurality of electronic components 10T and a routing structure 40T. The plurality of electronic components 10T are electrically connected to the routing structure 40T. The base member 41T (that will be described later) included in the subunit SUT is an example of a “second base member”.

In the present embodiment, the subunit SUS is a subunit SU in which a heat dissipation property is emphasized. The subunit SUS is disposed in the above first region R1 of the electrical connection unit 1. The subunit SUS faces a first region A1 of the metal plate 110 that will be described later in the Z direction.

On the other hand, the subunit SUT is a subunit SU in which the mountability is emphasized. The subunit SUT is disposed, for example, on the +Y direction side with respect to the subunit SUS. The subunit SUT is disposed in the above second region R2 of the electrical connection unit 1. The subunit SUT faces a second region A2 of the metal plate 110 that will be described later in the Z direction. Hereinafter, in a case where the electronic component 10S and the electronic component 10T are not distinguished, the electronic components are simply referred to as “electronic component 10”.

Note that the main body MU need not be divided into a plurality of subunits SU instead of the example described above. For example, the plurality of subunits SU may be integrally formed. For example, a base plate 41S of the routing board 40S and a base member 41T of the routing structure 40T, which will be described later, may be integrally formed by one piece member.

### 4. Constitution of Subunit SUS

Next, a constitution of the subunit SUS will be described.

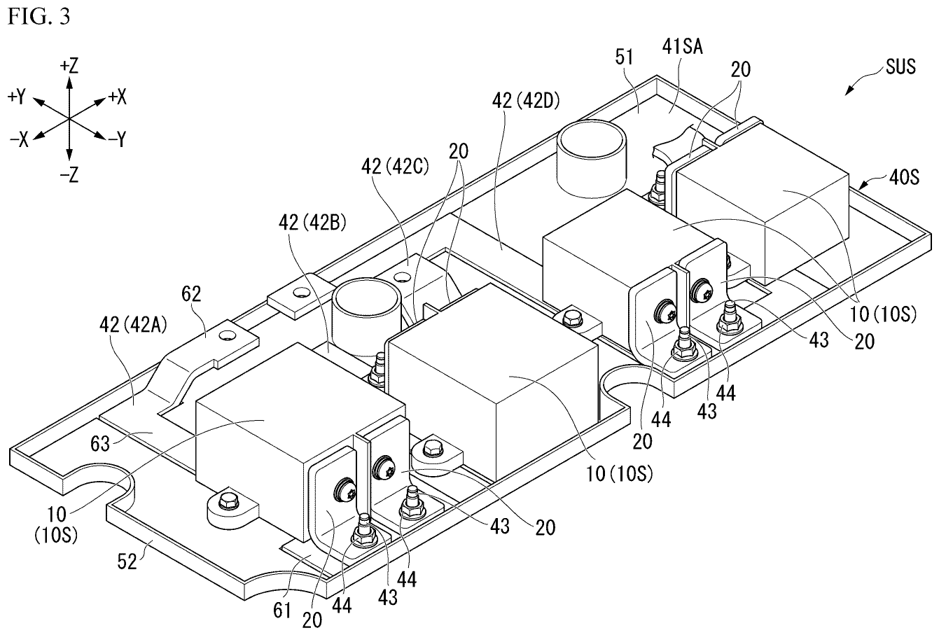

FIG. 3 is a perspective view for describing the subunit SUS. The subunit SUS includes, for example, a plurality of electronic components 10, a plurality of connection components 20, and a routing board 40S. The connection component 20 is a member forming an energization path in the vertical direction. The connection component 20 may be referred to as a “vertical routing member”.

### 4.1 Electronic Component

First, the electronic component 10 will be described. The electronic component 10 is an electronic component mounted according to a function required for each subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. However, the type of the electronic component 10 is not limited to the above example. The electronic component 10 is, for example, a heat generating component that generates heat at the time of energization.

In the present embodiment, the plurality of electronic components 10 include an electronic component 10S that generates relatively large heat when energized. The electronic component 10S is a relay (for example, a mechanical relay or a semiconductor relay), a pyrofuse, a current sensor (for example, a current sensor having a shunt resistor), or the like. However, the type of the electronic component 10S is not limited to the above example.

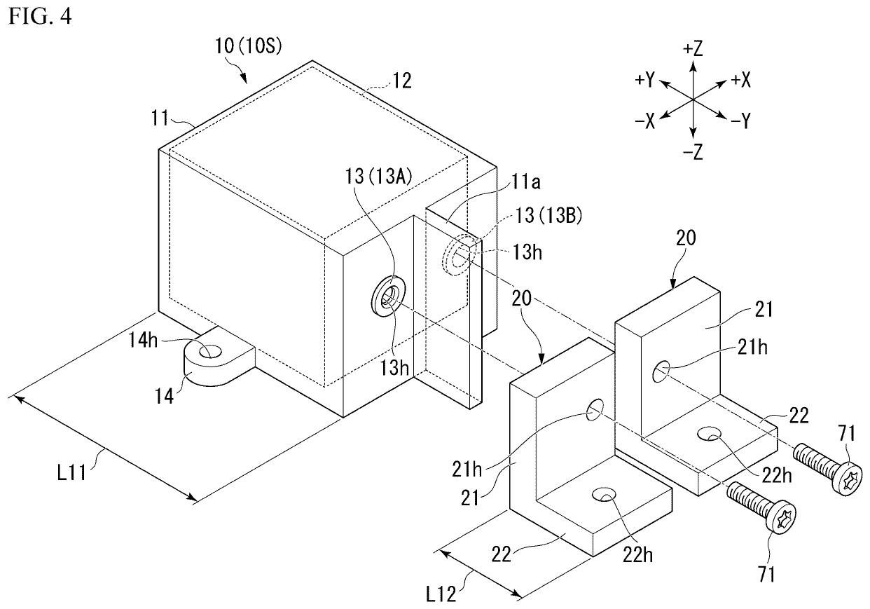

FIG. 4 is a perspective view illustrating the electronic component 10S and the connection component 20. The electronic component 10S is, for example, an electronic component in which a plurality of terminals 13 are disposed to be arranged at one end of the electronic component 10S. The electronic component 10S includes, for example, a case 11, a component body 12, a plurality of terminals 13, and a plurality of attachment portions 14.

### Case

The case 11 is an outer member that forms most of the outer shape of the electronic component 10S. The case 11 is made of, for example, synthetic resin and has an insulating property. The case 11 accommodates the component body 12. The case 11 and the component body 12 may be integrally formed.

In the present embodiment, the case 11 has an insulating rib 11a protruding in the horizontal direction (for example, the Y direction) and extending in the Z direction. The insulating rib 11a has, for example, a plate shape formed in the horizontal direction (for example, the Y direction) and the Z direction. The insulating rib 11a extends over the entire length of the case 11 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, a part of the insulating rib 11a is disposed between first portions 21 (that will be described later) of the two connection components 20 connected to the electronic component 10S. The insulating rib 11a electrically insulates between the first portions 21 of the two connection components 20 connected to the electronic component 10S.

### Component Body

The component body 12 is a portion that performs a main function of the electronic component 10S. For example, in a case where the electronic component 10S is a relay, the component body 12 includes a switch (for example, a contact) that switches between a conductive state and a non-conductive state. For example, in a case where the electronic component 10S is a fuse, the component body 12 includes a fusion portion that is fused when an overcurrent flows. For example, in a case where the electronic component 10S is a capacitor, the component body 12 includes a portion that accumulates electric charge.

### Terminal

The terminal 13 is an electrical connection portion exposed to the outside of the case 11. The terminal 13 is electrically connected to the component body 12 inside the case 11. In the present embodiment, the electronic component 10S includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side. One of the terminal 13A and the terminal 13B is an example of a “first terminal”. The other of the terminal 13A and the terminal 13B is an example of a “second terminal”.

In the present embodiment, the terminal 13A and the terminal 13B are provided at one end of the electronic component 10S in the horizontal direction (for example, the Y direction). The terminal 13A and the terminal 13B are disposed to be arranged in the horizontal direction (for example, the X direction). Each of the terminal 13A and the terminal 13B is directed in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the Y direction). An inner circumferential surface of the attachment hole 13h of the electronic component 10S has a screw groove.

### Attachment Portion

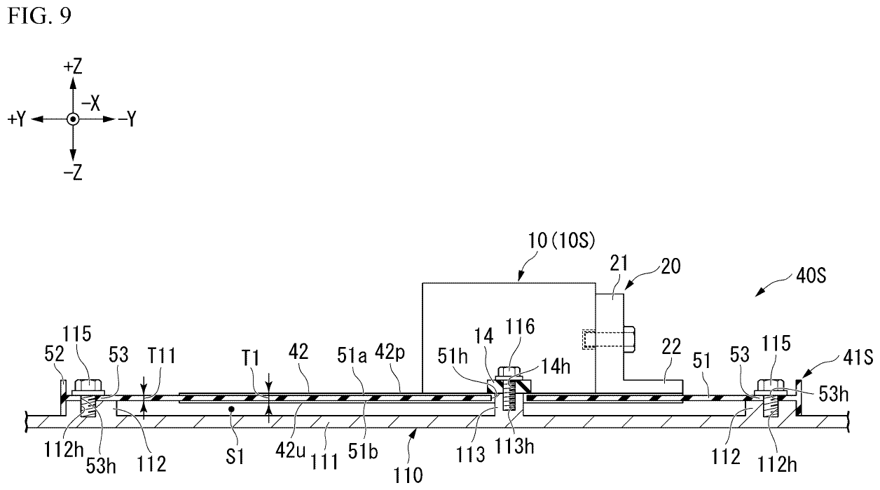

The attachment portion 14 is a portion for fixing the electronic component 10S. The attachment portion 14 has an attachment hole 14h to which a fastening member 116 (for example, a screw or a bolt; and see FIG. 9) that will be described later is attached. The attachment hole 14h is open in the Z direction. The attachment hole 14h is an insertion hole through which the fastening member 116 passes. A fixing destination of the attachment portion 14 will be described later.

### 4.2 Connection Component

Next, the connection component 20 will be described. The connection component 20 is a component that electrically connects the electronic component 10S to the routing board 40S. The connection component 20 forms a part of an energization path in the subunit SUS. The connection component 20 is made of metal (for example, made of copper, made of a copper alloy, made of aluminum, or made of an aluminum alloy). The connection component 20 may be referred to as a “metal component”.

In the present embodiment, the connection component 20 electrically connects the electronic component 10S to the bus bar 42 (see FIG. 3) included in the routing board 40S. In the present embodiment, a length L12 of the connection component 20 in the longitudinal direction (for example, the Y direction) of the electronic component 10S is smaller than a length L11 of the electronic component 10S in the longitudinal direction. The connection component 20 includes, for example, a first portion 21 and a second portion 22.

### First Portion

The first portion 21 of the connection component 20 is a portion connected to the terminal 13 of the electronic component 10S. The first portion 21 is a plate-shaped or rectangular parallelepiped portion extending in the Z direction. The first portion 21 extends in the Z direction along one end (for example, an end in the Y direction) of the electronic component 10S. The first portion 21 is a standing portion that stands in the Z direction with respect to the routing board 40S (for example, with respect to a bus bar 42 that will be described later). The first portion 21 is adjacent to the electronic component 10S in the horizontal direction (for example, the Y direction). For example, the first portion 21 is adjacent to the terminal 13 of the electronic component 10S in the horizontal direction (for example, the Y direction), and is connected to the terminal 13 of the electronic component 10S from the horizontal direction (for example, the Y direction).

The first portion 21 of the connection component 20 has a first attachment hole 21h through which the fastening member 71 (for example, a screw or a bolt) passes. The first attachment hole 21h is open in the horizontal direction (for example, the Y direction). The fastening member 71 that has passed through the first attachment hole 21h is engaged with the attachment hole 13h of the terminal 13 of the electronic component 10S, and thus the first portion 21 is physically and electrically connected to the terminal 13 of the electronic component 10S.

### Second Portion

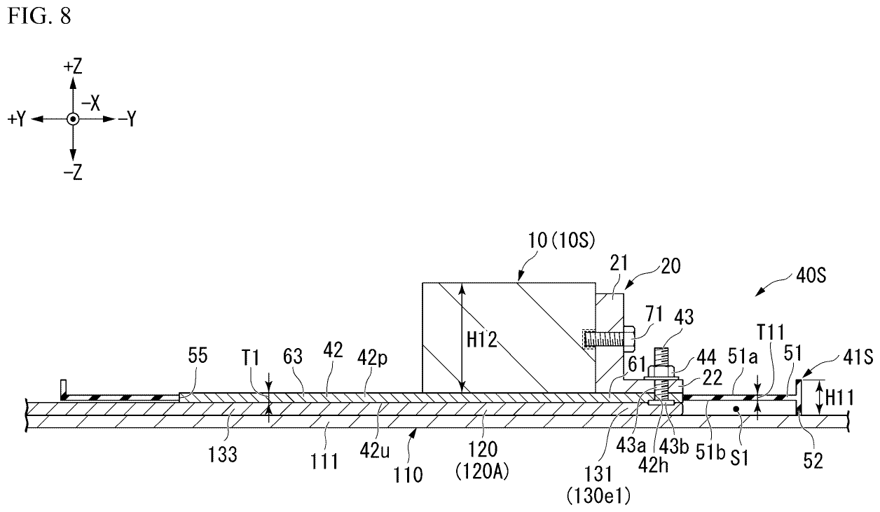

The second portion 22 of the connection component 20 is a portion connected to the bus bar 42 (see FIG. 3). The second portion 22 protrudes in the horizontal direction (for example, the Y direction) from the end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20 is attached to the fastening member 43 (for example, a screw or a bolt; and see FIG. 8) protruding from the bus bar 42 in the +Z direction from the Z direction, and is physically and electrically connected to the bus bar 42. In the present embodiment, the second portion 22 of the connection component 20 has a second attachment hole 22h through which the fastening member 43 passes. The second attachment hole 22h is open in the Z direction. In the second portion 22, the fastening member 43 passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42. In the present embodiment, the first portion 21 and the second portion 22 form one L-shaped connection component 20.

In the present embodiment, the bus bar 42 is disposed at a position away from the terminal 13 of the electronic component 10S (for example, a position away in the Z direction). The connection component 20 is disposed between the electronic component 10S and the bus bar 42. In the present disclosure, the phrase “the connection component is disposed between the electronic component and the bus bar” is not limited to a case where a part of the connection component is located between the electronic component and the bus bar when viewed from the X direction or the Y direction. The phrase “the connection component is disposed between the electronic component and the bus bar” may correspond to a case where a part of the connection component is located between the electronic component and the bus bar when viewed from a direction inclined with respect to the X direction or the Y direction. The connection component 20 electrically connects the terminal 13 of the electronic component 10S to the bus bar 42.

### 4.3 Routing Board

Next, the routing board 40S will be described.

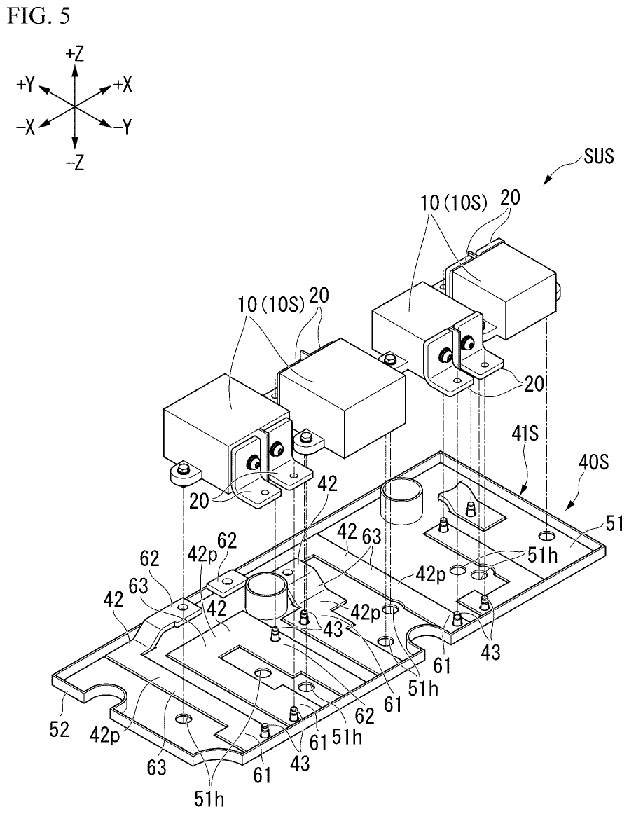

FIG. 5 is a perspective view for describing the routing board 40S. The routing board 40S is a member that forms at least a part of an energization path between a plurality of electronic components 10 (for example, a plurality of electronic components 10S) and/or at least a part of an energization path between the electronic component 10 (for example, the electronic component 10S) included in the subunit SUS and the electronic component 10 included in another subunit SU (for example, the subunit SUT). In the present disclosure, the “routing board”indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40S has a plate shape formed in the X direction and the Y direction.

The routing board 40S includes, for example, a base plate 41S, one or more (for example, a plurality of) bus bars 42, and a plurality of fastening members 43. In the present embodiment, the base plate 41S and the plurality of bus bars 42 are integrated through insert molding. For example, the routing board 40S is formed as one piece member by insert-molding the bus bar 42 with the base plate 41S after the fastening member 43 is fixed to the bus bar 42. That is, the bus bar 42 is integrated with the base plate 41S without using a fastening member such as a screw or a bolt. Note that the routing board 40S may be formed by using another structure instead of the insert molding. A modification example in which the routing board 40S is formed by using another structure will be described later.

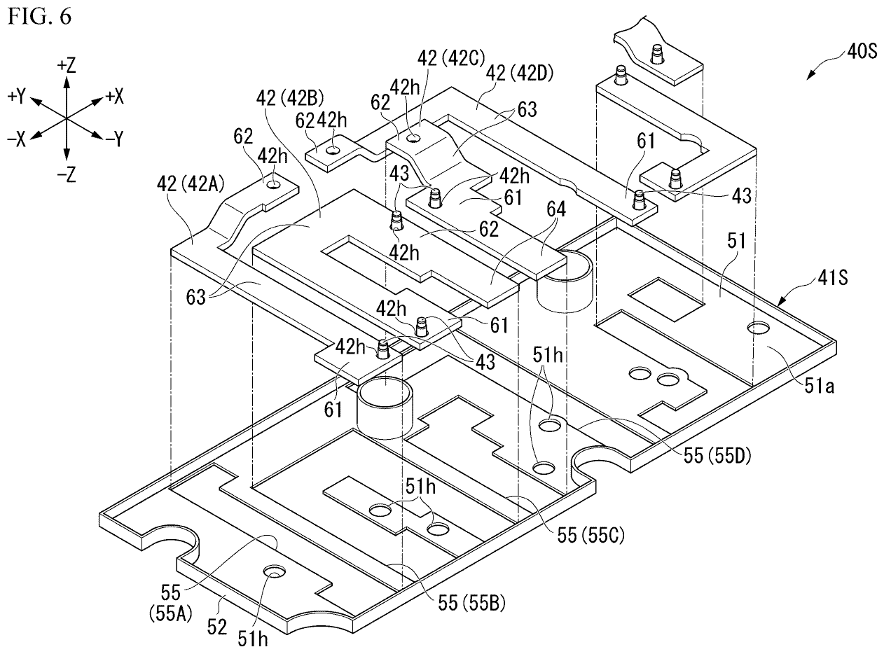

FIG. 6 is a partially exploded perspective view illustrating the routing board 40S. Hereinafter, for convenience of description, the base plate 41S, the bus bar 42, and the fastening member 43 will be described with reference to the drawings in which the routing board 40S is partially exploded.

### 4.3.1 Base Plate

The base plate 41S is a support member that integrally supports the plurality of bus bars 42 arranged at intervals in the horizontal direction. The base plate 41S is made of, for example, a synthetic resin and has an insulating property. The base plate 41S electrically insulates the plurality of bus bars 42 from each other. The base plate 41S is an example of a “base member”. The base plate 41S may be referred to as an “insulating substrate”. The base plate 41S includes, for example, a flat surface portion 51, a frame portion 52, and a plurality of fixing portions 53 (see FIG. 9).

### Flat Surface Portion

The flat surface portion 51 is a portion formed in a plate shape in the base plate 41S. The flat surface portion 51 has a plate shape formed in the horizontal direction. The flat surface portion 51 forms a main portion of the base plate 41S. The flat surface portion 51 forms a base portion (insulating base portion) of the base plate 41S. In the present embodiment, the flat surface portion 51 extends over the entire width in the X direction of the base plate 41S and over the entire width in the Y direction of the base plate 41S except for the frame portion 52 of the base plate 41S.

The flat surface portion 51 has a first surface 51a and a second surface 51b (see FIG. 9). The first surface 51a is a surface directed in the +Z direction. The first surface 51a is a flat surface provided in the horizontal direction. The first surface 51a faces the plurality of electronic components 10 (for example, the plurality of electronic components 10S). The second surface 51b is located on the side opposite to the first surface 51a. The second surface 51b is a surface directed in the −Z direction. The second surface 51b is a flat surface provided in the horizontal direction. The second surface 51b faces the metal plate 110 (see FIG. 2). A thickness direction (plate thickness direction) of the flat surface portion 51 is the Z direction. In the present embodiment, a thickness T11 of the flat surface portion 51 in the Z direction is smaller than a thickness T1 of the bus bar 42 in the Z direction (for example, a thickness of a horizontal plate portion 42p that will be described later in the Z direction) (see FIG. 8). The thickness T11 of the flat surface portion 51 in the Z direction may be equal to the thickness T1 of the bus bar 42 in the Z direction, or may be larger than the thickness T1 of the bus bar 42 in the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where a part of the entire length of the accommodation portion 55 penetrates the flat surface portion 51 in the Z direction (for example, the remaining portion of the accommodation portion 55 may be a recess recessed in the Z direction, or may be provided inside the base plate 41S and not exposed to the outside of the base plate 41S). Similarly, in the present disclosure, the phrase “the accommodation portion is recessed in the first direction (Z direction)” may include a case where a part of the entire length of the accommodation portion 55 is recessed in the Z direction (for example, a remaining portion of the accommodation portion 55 may be a through-hole penetrating the flat surface portion 51 in the Z direction, or may be provided inside the base plate 41S and not exposed to the outside of the base plate 41S).

Each accommodation portion 55 has an outer shape corresponding to the shape of the bus bar 42 to be accommodated when viewed from the Z direction. The plurality of accommodation portions 55 include, for example, four accommodation portions 55A, 55B, 55C, and 55D. The accommodation portion 55A is provided to correspond to a bus bar 42A that will be described later, and accommodates at least a part of the bus bar 42A. The accommodation portion 55B is provided to correspond to a bus bar 42B that will be described later, and accommodates at least a part of the bus bar 42B. The accommodation portion 55C is provided to correspond to a bus bar 42C that will be described later, and accommodates at least a part of the bus bar 42C. The accommodation portion 55D is provided to correspond to a bus bar 42D that will be described later, and accommodates at least a part of the bus bar 42D.

### Frame Portion

The frame portion 52 is provided at a peripheral end of the base plate 41S. The frame portion 52 is a reinforcement rib protruding vertically from the end of the flat surface portion 51 (see FIG. 8). A width (thickness) H11 of the frame portion 52 in the Z direction is, for example, less than half of a width (thickness) H12 of the electronic component 10 in the Z direction (see FIG. 8). Note that the frame portion 52 may be omitted.

### Fixing Portion

The fixing portion 53 is a portion fixed to the metal plate 110 (see FIG. 9). The fixing portion 53 has an attachment hole 53h penetrating the base plate 41S in the Z direction. A fastening member 115 (for example, a screw or a bolt) that will be described later passes through the attachment hole 53h. This content will be described later.

### 4.3.2 Bus Bar

The bus bar 42 is a routing member (electrical connection member) included in the routing board 40S. The bus bar 42 is, for example, a routing member for electrically connecting a plurality of electronic components (for example, a plurality of electronic components 10S). Alternatively, the bus bar 42 may be a routing member for electrically connecting the electronic component 10 (for example, the electronic component 10S) to the electronic component 10 included in another subunit SU (for example, the subunit SUT). The bus bar 42 is made of metal (for example, made of copper, made of a copper alloy, made of aluminum, or made of an aluminum alloy) and has conductivity. In the present embodiment, a plurality of bus bars 42, for example, four bus bars 42A, 42B, 42C, and 42D are included. The four bus bars 42A, 42B, 42C, and 42D are disposed to be arranged at intervals in the horizontal direction. The four bus bars 42A, 42B, 42C, and 42D include portions disposed on the same plane. The four bus bars 42A, 42B, 42C, and 42D are supported by the flat surface portion 51 of the base plate 41S. In the present disclosure, the phrase “the bus bar is supported by the flat surface portion” is not limited to the case where the bus bar 42 is accommodated in the accommodation portion 55, and may include a case where the bus bar 42 is attached to the first surface 51a or the second surface 51b of the flat surface portion 51.

At least a part of each bus bar 42 has a plate shape formed in the horizontal direction. At least a part of each bus bar 42 is accommodated in the accommodation portion 55 and extends along the flat surface portion 51. That is, at least a part of each bus bar 42 extends along the first surface 51a of the flat surface portion 51. At least a part of each bus bar 42 extends in the horizontal direction in the accommodation portion 55. Hereinafter, a portion of each bus bar 42 extending in a plate shape formed in the horizontal direction may be referred to as a “horizontal plate portion 42p”. The horizontal plate portion 42p is an example of a “plate portion”. The bus bar 42 is a member that forms a horizontal energization path. The bus bar 42 may be referred to as a “horizontal routing member”.

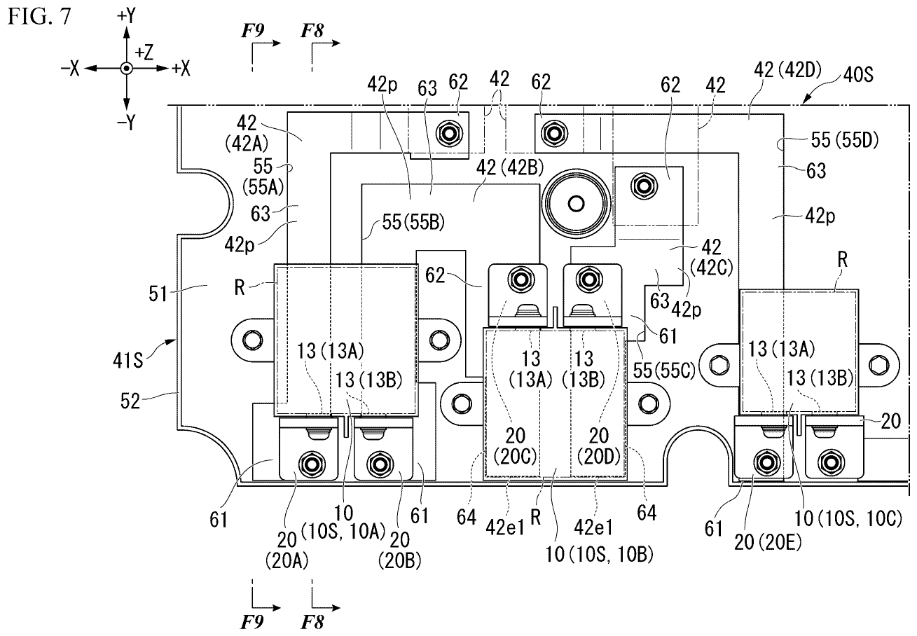

FIG. 7 is a plan view illustrating the subunit SUS. Each bus bar 42 includes, for example, a connection portion 61, a connection portion 62, and an extending portion 63.

The connection portion 61 is located in the middle of the bus bar 42 or at the first end of the bus bar 42. The connection portion 61 is a portion connected to the electronic component 10 (for example, the electronic component 10S) directly or via the connection component 20. The connection portion 61 includes, for example, a portion overlapping the connection component 20 when viewed from the Z direction. The connection portion 61 is adjacent to the connection component 20 in the Z direction and is connected to the connection component 20 from the Z direction. Instead of the above example, for example, the connection portion 61 may be adjacent to the terminal 13 of the electronic component 10 in the Z direction and directly connected to the terminal 13 of the electronic component 10 from the Z direction.

The connection portion 62 is located in the middle of the bus bar 42 or at the second end of the bus bar 42. The connection portion 62 is a portion connected to another electronic component 10 directly or via another connection component 20. Instead of the above example, the connection portion 62 may be connected to another bus bar 42(for example, the bus bar 42 included in another subunit SU) or an external connection bus bar 76 (see FIG. 2).

The extending portion 63 extends from the connection portion 61 in the X direction or the Y direction. The extending portion 63 is provided between the connection portion 61 and the connection portion 62. The extending portion 63 extends over the connection portion 61 and the connection portion 62. The extending portion 63 connects the connection portion 61 to the connection portion 62.

In the present embodiment, the horizontal plate portion 42p described above includes at least the entire connection portion 61 and a part of the extending portion 63. That is, at least the entire connection portion 61 and a part of the extending portion 63 are accommodated in the accommodation portion 55 and located on the same plane.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends over the region R overlapping the electronic component 10 when viewed from the Z direction, over the −Y direction side and the +Y direction side of the region R. That is, the bus bar 42 is accommodated in the accommodation portion 55 to be easily routed through a better path (for example, a path with a shorter distance) without being disturbed by the presence of the electronic component 10.

One or more bus bars 42 may have an extension 64 in addition to the connection portion 61, the connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the connection portion 61 (or the connection portion 62). The extension 64 has a plate shape formed in the horizontal direction. The extension 64 is included in the horizontal plate portion 42p. The extension 64 is accommodated in the accommodation portion 55 and extends along the flat surface portion 51. The extension 64 extends to the region R overlapping the electronic component 10 when viewed from the Z direction, and has an end 42e1 of the bus bar 42 at a position overlapping the electronic component 10 when viewed from the Z direction.

Some routing examples of the bus bar 42 will be described below. The plurality of electronic components 10S includes three electronic components 10A, 10B, and 10C. The plurality of connection components 20 includes five connection components 20A, 20B, 20C, 20D, and 20E.

The bus bar 42A has the connection portion 61, the connection portion 62, and the extending portion 63. The connection portion 61 is connected to the terminal 13A of the electronic component 10A via the connection component 20A. The connection portion 62 is disposed at the end of the subunit SUS on the +Y direction side and is connected to the bus bar 42 included in another subunit SU. The extending portion 63 is accommodated in the accommodation portion 55 to extend over both sides of the region R through the region R overlapping the electronic component 10A when viewed from the Z direction.

The bus bar 42B has the connection portion 61, the connection portion 62, the extending portion 63, and the extension 64. The connection portion 61 is connected to the terminal 13B of the electronic component 10A via the connection component 20B. The connection portion 62 is connected to the terminal 13A of the electronic component 10B via the connection component 20C. The extension 64 extends to the region R overlapping the electronic component 10B when viewed from the Z direction, and has an end 42e1 of the bus bar 42 at a position overlapping the electronic component 10B.

The bus bar 42C has the connection portion 61, the second connection portion 62, and the extending portion 63. The connection portion 61 is connected to the terminal 13B of the electronic component 10B via the connection component 20D. The connection portion 62 is disposed at the end of the subunit SUS on the +Y direction side and is connected to the bus bar 42 included in another subunit SU.

The bus bar 42D has the connection portion 61, the connection portion 62, and the extending portion 63. The connection portion 61 is connected to the terminal 13A of the electronic component 10C via the connection component 20E. The connection portion 62 is disposed at the end of the subunit SUS on the +Y direction side and is connected to the bus bar 42 included in another subunit SU.

### Exposure Structure on Upper Surface Side of Each Bus Bar

In the present embodiment, at least a part of the bus bar 42 is exposed to the upper surface side of the base plate 41S. For example, the connection portion 61, the connection portion 62, and the extending portion 63 of the bus bar 42 are exposed to the outside of the base plate 41S on the upper surface side (the first surface 51a side of the flat surface portion 51) of the base plate 41S. For example, the extending portion 63 of the bus bar 42 is exposed to the outside of the base plate 41S on the upper surface side of the base plate 41S at least over the entire length between the connection portion 61 and the connection portion 62.

### Exposure Structure on Lower Surface Side of Each Bus Bar

In the present embodiment, at least a part of the bus bar 42 is exposed to the lower surface side of the base plate 41S. For example, the entire connection portion 61 and at least a part of the extending portion 63 are exposed to the outside of the base plate 41S on the lower surface side of the base plate 41S (the second surface 51b side of the flat surface portion 51). In the present embodiment, a gap S1 is formed between the flat surface portion 51 of the base plate 41S and the metal plate 110 (see FIG. 9). The bus bar 42 includes an exposed portion 42u exposed to the gap S1 (see FIG. 9). The exposed portion 42u includes, for example, the entire connection portion 61 and at least a part of extending portion 63.

### 4.3.3 Fastening Member

Next, the fastening member 43 will be described.

FIG. 8 is a cross-sectional view taken along line F8-F8 of the structure illustrated in FIG. 7. The fastening member 43 is a component for fixing the bus bar 42 to the connection component 20 corresponding to the bus bar 42. The fastening member 43 is, for example, a caulking bolt fixed to the bus bar 42. The fastening member 43 is an example of a “fastening portion”.

In the present embodiment, at least one of the connection portion 61 and the connection portion 62 of the bus bar 42 has a through-hole 42h. The through-hole 42h penetrates the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 42h of the bus bar 42. With this fixation, the fastening member 43 is electrically and physically connected to the bus bar 42 in a state in which the shaft 43a protrudes in the +Z direction from the through-hole 42h of the bus bar 42. The fastening member 43 is not limited to caulking fixation, and may be fixed to the bus bar 42 through welding or other methods.

In the present embodiment, the connection component 20 is attached to the fastening member 43 from the Z direction in a state of being previously fixed to the electronic component 10 via the fastening member 71. For example, in the connection component 20, the shaft 43a of the fastening member 43 is inserted into the second attachment hole 22h of the second portion 22. The engagement member 44 (for example, a nut) is engaged with the shaft 43a of the fastening member 43 protruding from the second attachment hole 22h of the second portion 22 of the connection component 20. The engagement member 44 is attached to the shaft 43a in the Z direction. This engagement fixes the second portion 22 of the connection component 20 to the fastening member 43.

### Heat Transfer Member

First, the heat transfer member 120 will be described. The heat transfer member 120 is a member for transferring heat generated by the electronic component 10 (for example, the electronic component 10S) at the time of energization and/or heat (Joule heat) generated by the bus bar 42 itself at the time of energization to the metal plate 110. The heat transfer member 120 is, for example, a heat transfer sheet (for example, a thermally conductive silicone sheet) having elasticity. The heat transfer member 120 is made of a material having a higher thermal conductivity than the base plate 41S (or the base member 41T that will be described later), for example. However, the heat transfer member 120 is not limited to the above example, and may be a heat transfer member formed of a thermally conductive gel or another material. In the present embodiment, the heat transfer member 120 has an insulating property. The heat transfer member 120 is partially provided in the routing board 40S (see FIG. 2).

In the present embodiment, the plurality of heat transfer members 120 include one or more (for example, a plurality of) heat transfer members 120A (see FIG. 2). The heat transfer member 120A is a heat transfer member 120 having a function of transferring heat from the first region R1 toward the second region R2 of the electrical connection unit 1.

In the present embodiment, the heat transfer member 120 (for example, the heat transfer member 120A) is disposed at a position overlapping a part of the bus bar 42 when viewed from the Z direction. Part of the heat transfer member 120 (for example, the heat transfer member 120A) is disposed between the bus bar 42 and the first region A1 of a flat surface portion 111 of the metal plate 110 that will be described later. In the present embodiment, part of the heat transfer member 120 (for example, the heat transfer member 120A) is disposed between the exposed portion 42u of the bus bar 42 and the flat surface portion 111 of the metal plate 110, and is in contact with each of the exposed portion 42u of the bus bar 42 and the first region Al of the flat surface portion 111 of the metal plate 110. Part of the heat transfer member 120 (for example, the heat transfer member 120A) transfers heat transferred from the electronic component 10 (for example, the electronic component 10S) to the bus bar 42 and/or heat generated by the bus bar 42, from the bus bar 42 to the first region Al of the flat surface portion 111 of the metal plate 110.

In the present embodiment, the heat transfer member 120A includes, for example, a first portion 131, a second portion 132, and a third portion 133 (see FIG. 2). Here, the first portion 131 will be described, and the second portion 132 and the third portion 133 will be described later.

The first portion 131 of the heat transfer member 120A forms, for example, a first end 130e1 which is an end of the heat transfer member 120A in the −Y direction. The first portion 131 is disposed at a position overlapping a part of the bus bar 42 in the vicinity of the electronic component 10 (for example, the electronic component 10S) when viewed from the Z direction. In the present embodiment, the first portion 131 is disposed at a position overlapping the connection component 20 when viewed from the Z direction. In other words, the first portion 131 is disposed at a position overlapping the connection portion 61 or the connection portion 62 of the bus bar 42 when viewed from the Z direction. The first portion 131 transfers heat moving from the electronic component 10S to the bus bar 42 via the connection component 20, from the bus bar 42 to the first region A1 of the flat surface portion 111 of the metal plate 110.

### 4.4 Fixing Structure of Routing Board and Electronic Component

Next, a fixing structure of the routing board 40S and the electronic component 10 will be described.

FIG. 9 is a cross-sectional view taken along line F9-F9 of the structure illustrated in FIG. 7. The metal plate 110 includes, for example, a fixing portion 112 and a fixing portion 113 in addition to a flat surface portion 111 that will be described later.

The fixing portion 112 is a fixing portion for fixing the base plate 41S to the metal plate 110. The fixing portion 112 is provided at a position corresponding to the fixing portion 53 of the base plate 41S when viewed from the Z direction. The fixing portion 112 is a cylindrical or prismatic boss protruding in the +Z direction from the flat surface portion 111 of the metal plate 110. The fixing portion 112 has an engagement hole 112h that is open in the +Z direction. An inner circumferential surface of the engagement hole 112h has a screw groove.

As described above, the fixing portion 53 of the base plate 41S has an attachment hole 53h. A fastening member 115 (for example, a screw or a bolt) passes through the attachment hole 53h. When the fastening member 115 that has passed through the attachment hole 53h of the fixing portion 53 of the base plate 41S is engaged with the engagement hole 112h of the fixing portion 112 of the metal plate 110, the base plate 41S is fixed to the metal plate 110.

The fixing portion 113 is a fixing portion for directly fixing the electronic component 10 (for example, the electronic component 10S) to the metal plate 110 without the base plate 41S interposed therebetween. The fixing portion 113 is provided at a position corresponding to the attachment portion 14 of the electronic component 10 when viewed from the Z direction. The fixing portion 113 is a cylindrical or prismatic boss protruding in the +Z direction from the flat surface portion 111. The fixing portion 113 has an engagement hole 113h that is open in the +Z direction. An inner circumferential surface of the engagement hole 113h has a screw groove.

In the present embodiment, the flat surface portion 51 of the base plate 41S has a through-hole 51h. The through-hole 51h penetrates the flat surface portion 51 in the Z direction. The through-hole 51h is provided at a position corresponding to the fixing portion 113 of the metal plate 110 when viewed from the Z direction. The fixing portion 113 of the metal plate 110 passes through the through-hole 51h of the base plate 41S and protrudes to the same position as the first surface 51a of the flat surface portion 51 or further toward the +Z direction side than the first surface 51a of the flat surface portion 51. The attachment portion 14 of the electronic component 10 is in contact with the fixing portion 113 at the same position as the first surface 51a of the flat surface portion 51 or at a position located further toward the +Z direction side than the first surface 51a of the flat surface portion 51.

A fastening member 116 (for example, a screw or a bolt) passes through the attachment hole 14h of the attachment portion 14 of the electronic component 10 from the +Z direction side. When the fastening member 116 that has passed through the attachment hole 14h of the attachment portion 14 of the electronic component 10 is engaged with the engagement hole 113h of the fixing portion 113 of the metal plate 110, the electronic component 10 is fixed to the metal plate 110 without the base plate 41S interposed therebetween. Note that, instead of the above-described example, the electronic component 10 may be fixed to a fixing portion provided in the base plate 41S.

### 5. Constitution of Subunit Sut

Next, a constitution of the subunit SUT will be described.

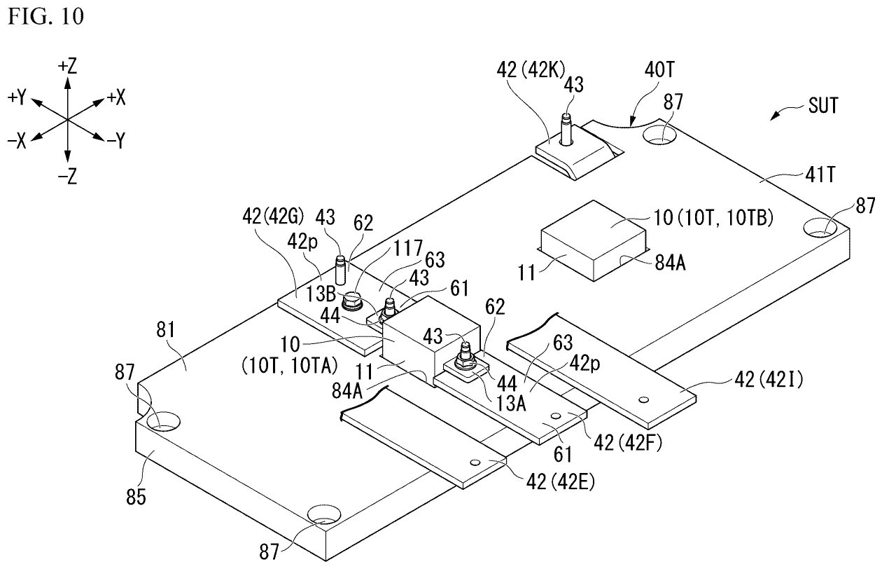

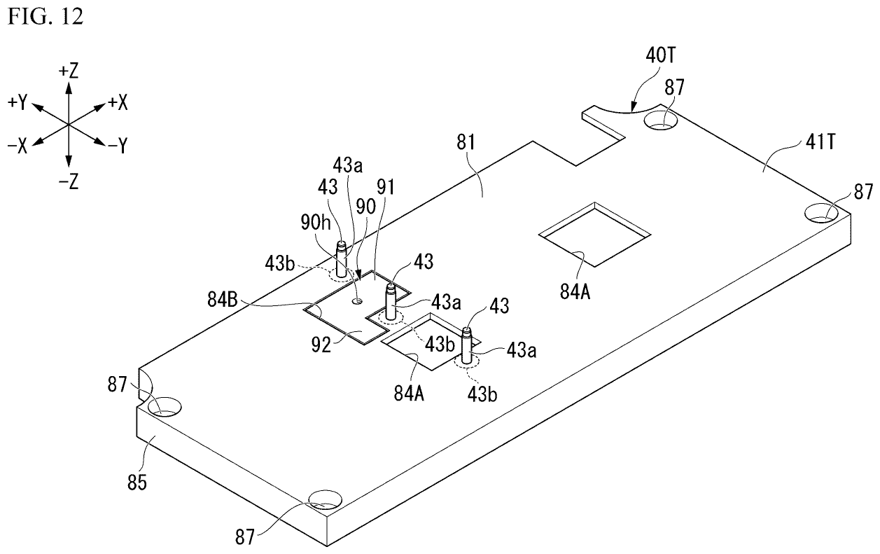

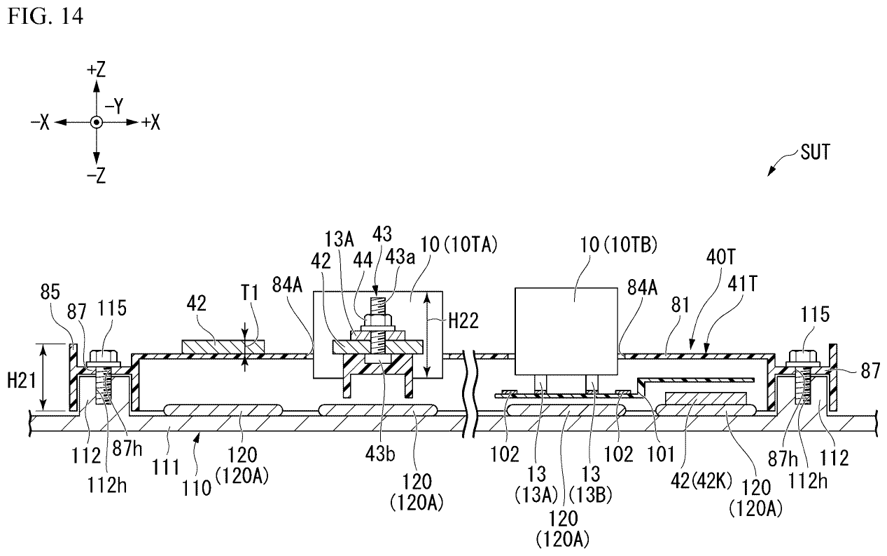

FIG. 10 is a perspective view illustrating the subunit SUT. The subunit SUT includes, for example, a plurality of electronic components 10, a routing structure 40T, an auxiliary base member 101 (see FIG. 14), and a metal portion 90 (see FIG. 12).

### 5.1 Electronic Component

First, the electronic component 10 will be described. The plurality of electronic components 10 include a plurality of electronic components 10TA (only one is illustrated in FIG. 12) and a plurality of electronic components 10TB (only one is illustrated in FIG. 12). Note that the plurality of electronic components 10 may include only one of the electronic component 10TA and the electronic component 10TB.

The electronic component 10TA is an example of the electronic component 10T described above. The electronic component 10TA is an electronic component having a smaller amount of heat generation than the electronic component 10S when energized. On the other hand, the electronic component 10TB is another example of the electronic component 10T described above. The electronic component 10TB is an electronic component having a lower mountability (for example, requiring a complicated implementation structure) than the electronic component 10S. The electronic component 10TB has, for example, a terminal 13 protruding in the −Z direction toward the flat surface portion 111 of the metal plate 110 (see FIG. 14). For example, the electronic component 10TB has a smaller amount of heat generation than the electronic component 10S when energized.

Hereinafter, in a case where the electronic component 10TA and the electronic component 10TB are not distinguished, the electronic components are simply referred to as “electronic component 10T”. The electronic component 10T is, for example, a connector, a fuse, a capacitor, a branch component, any of various sensors (for example, a current sensor or a voltage sensor), an electronic control unit, or an electronic component unit in which two or more of these are unitized. However, the type of the electronic component 10T is not limited to the above example.

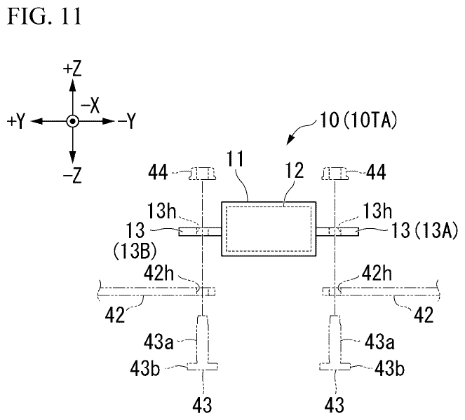

FIG. 11 is a front view illustrating the electronic component 10TA. The electronic component 10TA is, for example, an electronic component in which a plurality of terminals 13 are separately disposed at both ends of the electronic component 10TA in the horizontal direction. In the present embodiment, the terminal 13A and the terminal 13B are disposed separately at both ends of the electronic component 10TA in the Y direction. The terminals 13A and 13B protrude in the horizontal direction (for example, the +Y direction or the −Y direction) from the center of the case 11 in the Z direction. Each terminal 13 has an attachment hole 13h through which a fastening member 43 (for example, a screw or a bolt) passes. The attachment hole 13h is open in the Z direction.

### 5.2 Routing Structure

Next, referring to FIG. 10 again, the routing structure 40T will be described. The routing structure 40T is a member that forms at least a part of an energization path between the plurality of electronic components 10 (for example, the plurality of electronic components 10T) and/or at least a part of an energization path between the electronic component 10 (for example, the electronic component 10T) included in the subunit SUT and the electronic component 10 included in another subunit SU (for example, the subunit SUS). The routing structure 40T includes, for example, a base member 41T, one or more (for example, a plurality of) bus bars 42, and a plurality of fastening members 43. Note that the content of the fastening member 43 is similar to that of the fastening member 43 described in the subunit SUS, and thus repeated description will be omitted.

### 5.2.1 Base Member

FIG. 12 is a perspective view illustrating the base member 41T. The base member 41T is a support member that integrally supports the plurality of bus bars 42 arranged at intervals in the horizontal direction. The base member 41T is made of, for example, a synthetic resin and has an insulating property. The base member 41T electrically insulates the plurality of bus bars 42 from each other by using, for example, a rib (not illustrated). The base member 41T may be referred to as an “insulating substrate”. The base member 41T has a three-dimensional structure thicker in the Z direction than the base plate 41S included in the subunit SUS. The base member 41T includes, for example, a support wall 81, a frame portion 85 (peripheral wall portion), and a fixing portion 87.

### Support Wall

The support wall 81 is, for example, a plate-shaped wall portion provided in the horizontal direction. The plurality of bus bars 42 are disposed on the support wall 81 and are supported from below by the support wall 81 (see FIG. 10). The support wall 81 that supports the bus bar 42 is not limited to a wall portion provided in the horizontal direction, and may be a grid-shaped wall portion formed by a plurality of ribs extending in the Z direction. In the present embodiment, the fastening member 43 is attached to the support wall 81. The fastening member 43 protrudes from the support wall 81 in the +Z direction.

### Accommodation Portion Accommodating Electronic Component

In the present embodiment, the base member 41T has an accommodation portion 84A that is open to the +Z direction side. The accommodation portion 84A is, for example, a recess in which a part of the support wall 81 is recessed in the Z direction or a through-hole penetrating the support wall 81 in the Z direction. The accommodation portion 84A has an outer shape corresponding to the shape of the case 11 (that is, the component body 12) of the electronic component 10 (for example, the electronic component 10T) when viewed from the Z direction. At least a part of the electronic component 10 (for example, the electronic component 10T) (for example, at least a part of the component body 12) is accommodated in the accommodation portion 84A. At least a part of the electronic component 10 accommodated in the accommodation portion 84A is located on the −Z direction side compared with the support wall 81.

### Accommodation Portion Accommodating Metal Portion

In the present embodiment, the base member 41T has an accommodation portion 84B that is open to the +Z direction side. The accommodation portion 84B is, for example, a recess in which a part of the support wall 81 is recessed in the Z direction or a through-hole penetrating the support wall 81 in the Z direction. The accommodation portion 84B has an outer shape corresponding to the shape of the metal portion 90 that will be described later when viewed from the Z direction. At least a part of the metal portion 90 is accommodated in the accommodation portion 84B. At least a part of the metal portion 90 accommodated in the accommodation portion 84B is located on the −Z direction side compared with the support wall 81.

### Drame Portion

The frame portion 85 is provided at a peripheral end of the base member 41T. The frame portion 85 is a rib (peripheral wall portion) extending in the Z direction at the peripheral end of the base member 41T. A width (thickness) H21 in the Z direction of the frame portion 85 (peripheral wall portion) is, for example, half or more of a width (thickness) H22 in the Z direction of the electronic component 10 (for example, the electronic component 10TA) (see FIG. 14). Note that the frame portion 85 may be omitted.

### Fixing Portion

The fixing portion 87 is a portion fixed to the metal plate 110 (see FIG. 14). The fixing portion 87 faces the fixing portion 112 of the metal plate 110 in the Z direction. The fixing portion 87 has an attachment hole 87h penetrating the base member 41T in the Z direction. A fastening member 115 (for example, a screw or a bolt) passes through the attachment hole 87h. When the fastening member 115 that has passed through the attachment hole 87h is engaged with the engagement hole 112h of the fixing portion 112 of the metal plate 110, the base member 41T is fixed to the metal plate 110.

### 5.2.2 Bus Bar

Next, the bus bar 42 included in the routing structure 40T will be described.

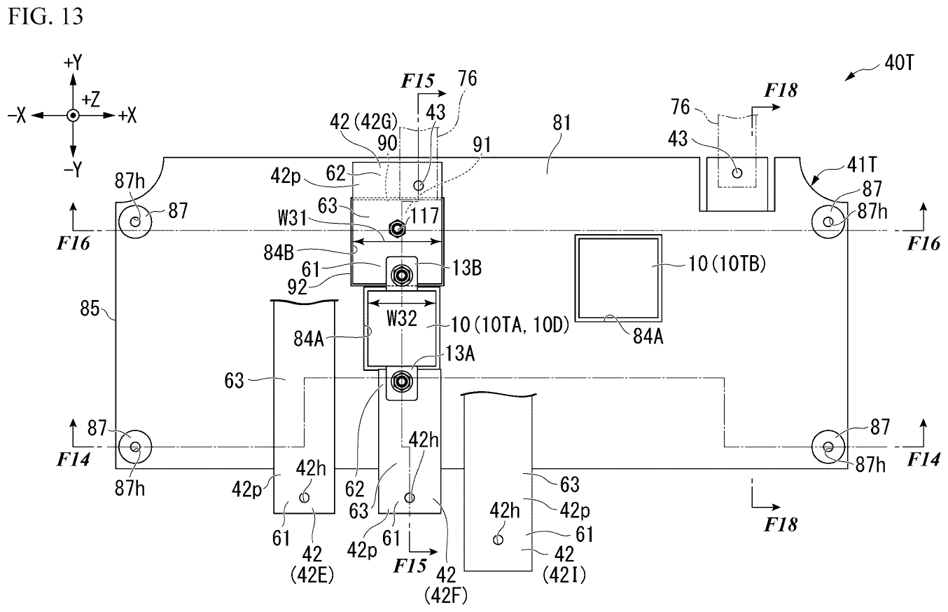

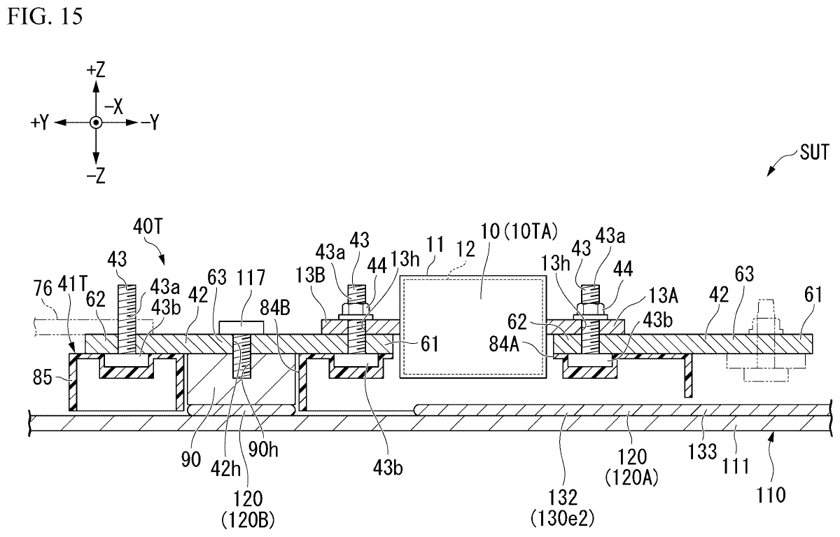

FIG. 13 is a plan view illustrating the subunit SUT. The bus bar 42 is a routing member (electrical connection member) included in the routing structure 40T. The bus bar 42 is, for example, a routing member for electrically connecting a plurality of electronic components 10 (for example, a plurality of electronic components 10T). Alternatively, the bus bar 42 may be a routing member for connecting the electronic component 10 (for example, the electronic component 10T) to the electronic component 10 included in another subunit SU (for example, the subunit SUS). In the present embodiment, the plurality of bus bars 42 are supported from below by the base member 41T and are disposed at positions away from the metal plate 110. The bus bar 42 is disposed immediately below the terminal 13 of the electronic component 10, for example. The bus bar 42 overlaps the component body 12 of the electronic component 10 when viewed from the X direction or the Y direction (see FIG. 15).

The plurality of bus bars 42 include, for example, four bus bars 42E, 42F, 42G, and 42I. The four bus bars 42E, 42F, 42G, and 42I are disposed to be arranged at intervals in the horizontal direction. The four bus bars 42E, 42F, 42G, and 42I include portions disposed on the same plane. At least a part of each bus bar 42 is the horizontal plate portion 42p. In the present embodiment, each bus bar 42 has a plate shape formed in the horizontal direction over the entire length. The horizontal plate portion 42p of each bus bar 42 includes the connection portion 61, the connection portion 62, and the extending portion 63. In the present embodiment, the subunit SUT includes an electronic component 10D as one of the plurality of electronic components 10 TA.

The connection portion 61 of the bus bar 42E is connected to the bus bar 42 included in the subunit SUS. Similarly, the connection portion 61 of the bus bar 42F is connected to the bus bar 42 included in the subunit SUS. The connection portion 62 of the bus bar 42F is physically and electrically connected to the terminal 13A of the electronic component 10D. For example, the terminal 13A of the electronic component 10D is placed on the horizontal plate portion 42p of the bus bar 42F to be connected to the connection portion 62 of the bus bar 42F.

The connection portion 61 of the bus bar 42G is physically and electrically connected to the terminal 13B of the electronic component 10D. For example, the terminal 13B of the electronic component 10D is placed on the horizontal plate portion 42p of the bus bar 42G to be connected to the connection portion 61 of the bus bar 42G. The connection portion 62 of the bus bar 42G is physically and electrically connected to the external connection bus bar 76. The connection portion 62 of the bus bar 42G is connected to an external device via the bus bar 76. The bus bar 76 is an example of an “external connection component”. Note that the connection portion 62 of the bus bar 42G may be physically and electrically connected to the terminal 13 of another electronic component 10 instead of the bus bar 76.

The connection portion 61 of the bus bar 42I is connected to the bus bar 42 included in the subunit SUS. The connection portion 62 of the bus bar 42I is physically and electrically connected to the terminal 13A of the electronic component 10T (not illustrated).

### 5.3 Auxiliary Base Member

Next, the auxiliary base member 101 will be described.

FIG. 14 is a cross-sectional view taken along line F14-F14 of the structure illustrated in FIG. 13. The auxiliary base member 101 is made of, for example, a synthetic resin and has an insulating property. A plurality of wirings 102 are provided on the surface of the auxiliary base member 101. The wiring 102 is, for example, a conductive layer (metal layer) provided on the surface of the auxiliary base member 101. The auxiliary base member 101 is disposed between the base member 41T and the flat surface portion 111 of the metal plate 110 in the Z direction. The auxiliary base member 101 faces the electronic component 10TB from the −Z direction side. The terminal 13 of the electronic component 10TB is electrically connected to the wiring 102 provided on the auxiliary base member 101 at a position between the base member 41T and the flat surface portion 111 of the metal plate 110. The auxiliary base member 101 is an example of a “third base member”.

### 5.4 Metal Portion

Next, the metal portion 90 will be described with reference to FIG. 12. The metal portion 90 is, for example, a structure that reduces thermal interference from an external device to the electronic component 10 included in the subunit SUT.

The metal portion 90 is, for example, a heat transfer portion that transfers part of heat directed from an external device to the electronic component 10 (for example, the electronic component 10T) via the bus bar 76 to the flat surface portion 111 of the metal plate 110 that will be described later. Alternatively, the metal portion 90 may be a heat transfer portion that transfers at least part of heat generated by the electronic component 10 and/at least part of heat generated by the bus bar 42 itself to the flat surface portion 111 of the metal plate 110. The flat surface portion 111 of the metal plate 110 is disposed away from the bus bar 42 in the Z direction. The flat surface portion 111 of the metal plate 110 faces the bus bar 42 in the Z direction. The flat surface portion 111 of the metal plate 110 is an example of a “facing portion”.

The metal portion 90 is, for example, a heat storage member (heat absorbing member) that increases the heat capacity of the energization path included in the subunit SUT. The metal portion 90 stores (absorbs) part of heat directed from an external device to the electronic component 10 (for example, the electronic component 10TA) via the bus bar 76, for example. Alternatively, the metal portion 90 may store (absorb) at least part of heat generated by the electronic component 10 and/at least part of heat generated by the bus bar 42 itself. In a case where the metal portion 90 is used as a heat storage member, the metal portion 90 need not be thermally connected to the metal plate 110.

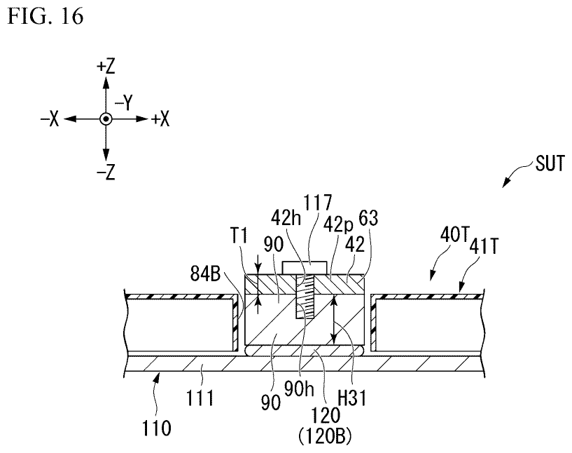

FIG. 15 is a cross-sectional view taken along line F15-F15 of the structure illustrated in FIG. 13. FIG. 16 is a cross-sectional view taken along line F16-F16 of the structure illustrated in FIG. 13. In the present embodiment, the metal portion 90 is provided separately from the metal plate 110. The metal portion 90 is, for example, a solid metal block. A shape of the metal portion 90 is not limited to the above example. The metal portion 90 may be a member having an I-shaped, L-shaped, or C-shaped cross-sectional shape. The metal portion 90 may be integrally formed with the base member 41T through insert molding.

A thickness H31 of the metal portion 90 in the Z direction is larger than the thickness T1 of the horizontal plate portion 42p of the bus bar 42 in the Z direction. For example, the thickness H31 of the metal portion 90 in the Z direction is twice or more the thickness T1 of the horizontal plate portion 42p of the bus bar 42 in the Z direction.

In the present embodiment, a width W31 of the metal portion 90 in the X direction is larger than a width W32 of the electronic component 10 in the X direction (see FIG. 13). From another point of view, the width W31 (see FIG. 13) of the metal portion 90 in the X direction is larger than the above thickness H31 (see FIG. 16) of the metal portion 90 in the Z direction.

In the present embodiment, the base member 41T is disposed between the bus bar 42 and the flat surface portion 111 of the metal plate 110. The base member 41T has an accommodation portion 84B that is open in the Z direction. At least a part of the metal portion 90 is accommodated in the accommodation portion 84B.

The metal portion 90 is disposed between the bus bar 42 and the flat surface portion 111 of the metal plate 110 in the Z direction. The metal portion 90 faces the bus bar 42 from the Z direction and is thermally connected to the bus bar 42.

In the present embodiment, the metal portion 90 is disposed, for example, between the extending portion 63 of the bus bar 42 and the flat surface portion 111 of the metal plate 110. The metal portion 90 faces the extending portion 63 of the bus bar 42 from the Z direction, and is thermally connected to the extending portion 63 of the bus bar 42.

In the present embodiment, the metal portion 90 has an engagement hole 90h that is open in the +Z direction. The inner peripheral surface of the engagement hole 90h has a screw groove. The extending portion 63 of the bus bar 42 has a through-hole 42h facing the engagement hole 90h. A fastening member 117 (for example, a screw or a bolt) passes through the through-hole 42h of the bus bar 42 from the +Z direction side. When the fastening member 117 that has passed through the through-hole 42h of the bus bar 42 is engaged with the engagement hole 90h of the metal portion 90, the extending portion 63 of the bus bar 42 is fixed to the metal portion 90.

In the present embodiment, the heat transfer member 120B is disposed between the metal portion 90 and the flat surface portion 111 of the metal plate 110. The heat transfer member 120B is an example of the heat transfer member 120 described above. Instead of/in addition to the above example, the heat transfer member 120B may be disposed between the metal portion 90 and the bus bar 42.

As illustrated in FIG. 13, when viewed from the Z direction, the metal portion 90 is disposed between the terminal 13B of the electronic component 10 and the external connection bus bar 76. Therefore, heat directed from the bus bar 76 to the electronic component 10 through the bus bar 42 easily moves to the metal portion 90 before reaching the electronic component 10.

The metal portion 90 includes, for example, a first portion 91 and a second portion 92. The first portion 91 is located on the +Y direction side with respect to the terminal 13B of the electronic component 10 when viewed from the Z direction. The second portion 92 is located on the −X direction side or the +X direction side with respect to the terminal 13B of the electronic component 10 when viewed from the Z direction. The first portion 91 and the second portion 92 are integrally formed. According to such a constitution, it is easy to secure a larger volume of the metal portion 90 compared with the metal portion 90 having a rectangular parallelepiped shape.

### 6. Coupling Structure of Subunit

Next, a coupling structure between the plurality of subunits SU will be described.

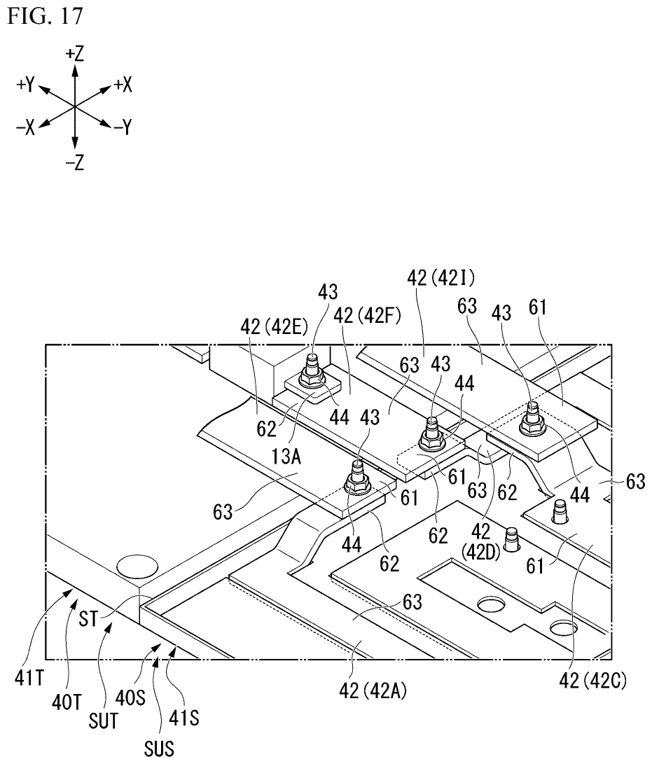

FIG. 17 is a perspective view illustrating a coupling structure between the subunit SUS and the subunit SUT. In the present embodiment, a step ST based on a difference in height in the Z direction between the base plate 41S of the subunit SUS and the base member 41T of the subunit SUT is formed between the subunit SUS and the subunit SUT. An intersection structure in which the bus bar 42 included in the subunit SUS and the bus bar 42 included in the subunit SUT three-dimensionally intersect is realized by using the step ST.

For example, the bus bars 42E, 42F, and 42I included in the subunit SUT maintain the height in the Z direction supported by the base member 41T and extend in the −Y direction to a position overlapping the base plate 41S of the subunit SUS in the Z direction. The connection portion 61 of each of the bus bars 42E, 42F, and 42I is separated from the base plate 41S of the subunit SUS in the Z direction and faces the base plate 41S of the subunit SUS in the Z direction.

On the other hand, the connection portion 62 of the bus bar 42A included in the subunit SUS is raised in the +Z direction with respect to the extending portion 63 of the bus bar 42A, and is in contact with the connection portion 61 of the bus bar 42E from the −Z direction side. The connection portion 62 of the bus bar 42A and the connection portion 61 of the bus bar 42E are fixed by the fastening member 43 and the engagement member 44.

Similarly, the connection portion 62 of the bus bar 42C included in the subunit SUS is raised in the +Z direction with respect to the extending portion 63 of the bus bar 42C, and is in contact with the connection portion 61 of the bus bar 42I from the −Z direction side. The connection portion 62 of the bus bar 42C and the connection portion 61 of the bus bar 42I are fixed by the fastening member 43 and the engagement member 44.

The extending portion 63 of the bus bar 42D included in the subunit SUS extends in the X direction through between the flat surface portion 111 of the metal plate 110 and the bus bar 42I. For example, the extending portion 63 of the bus bar 42D passes through a region overlapping the bus bar 42I when viewed from the Z direction, and extends over the +X direction side and the −X direction side of the bus bar 42I. The connection portion 62 of the bus bar 42D is raised in the +Z direction with respect to the extending portion 63 of the bus bar 42D, and is in contact with the connection portion 61 of the bus bar 42F from the −Z direction side. The connection portion 62 of the bus bar 42D and the connection portion 61 of the bus bar 42F are fixed by the fastening member 43 and the engagement member 44.

### 7. Extending Structure of Bus Bar

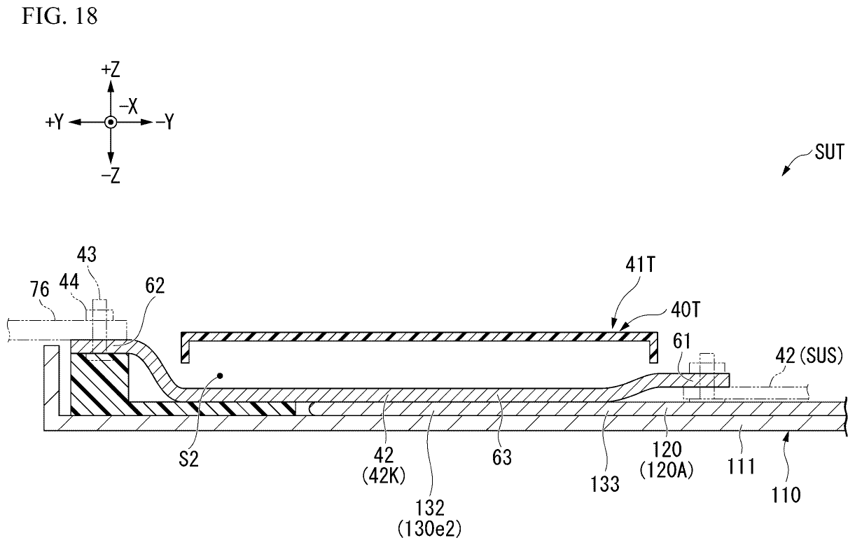

FIG. 18 is a cross-sectional view taken along line F18-F18 of the structure illustrated in FIG. 13. In the present embodiment, one bus bar 42 (bus bar 42K) is disposed between the base member 41T and the flat surface portion 111 of the metal plate 110, and extends in the Y direction in a gap S2 between the base member 41T and the flat surface portion 111 of the metal plate 110. The bus bar 42K is disposed, for example, between the auxiliary base member 101 and the flat surface portion 111 of the metal plate 110. The bus bar 42K extends, for example, over the −Y direction side and the +Y direction side of the base member 41T. The connection portion 61 of the bus bar 42K is physically and electrically connected to the bus bar 42 included in the subunit SUS. The connection portion 62 of the bus bar 42K is physically and electrically connected to the external connection bus bar 76.

### 8. Metal Plate and Insulating Cover

Next, referring to FIG. 2 again, the metal plate 110 and the insulating cover 119 will be described.

### 8.1 Metal Plate

The metal plate 110 is a member that secures rigidity of the electrical connection unit 1 and enhances the heat dissipation property of the electrical connection unit 1. The metal plate 110 is made of metal (for example, aluminum or an aluminum alloy). The metal plate 110 is an example of a “heat dissipation member”. The metal plate 110 may be referred to as a “metal member” or a “rigid member”.

The metal plate 110 has a rectangular shape formed in the X direction and the Y direction. The metal plate 110 has a first end 110e1, a second end 110e2, a third end 110e3, and a fourth end 110e4. The first end 110e1 and the second end 110e2 are a pair of ends of the metal plate 110 in the longitudinal direction, and are separated in the X direction. The third end 110e3 and the fourth end 110e4 are a pair of ends of the metal plate 110 in the lateral direction, and are separated in the Y direction. The metal plate 110 includes, for example, the flat surface portion 111, the plurality of fixing portions 112 (see FIG. 9) described above, and the plurality of fixing portions 113 (see FIG. 9) described above.

The flat surface portion 111 is a portion formed in a plate shape in the metal plate 110. The flat surface portion 111 has a plate shape formed in the horizontal direction. The flat surface portion 111 forms a main portion of the metal plate 110. The flat surface portion 111 forms a base portion (metal base portion) of the metal plate 110. The flat surface portion 111 has a size that covers the two subunits SU from below.

In the present embodiment, the flat surface portion 111 has a first region A1 and a second region A2. The first region A1 is, for example, a region on the −Y direction side in the flat surface portion 111. The subunit SUS described above faces the first region A1 of the flat surface portion 111 when viewed from the Z direction. That is, the plurality of electronic components 10S and the base plate 41S included in the subunit SUS face the first region A1 of the flat surface portion 111 in the Z direction.

The second region A2 is, for example, a region on the +Y direction side in the flat surface portion 111. The above-described subunit SUT faces the second region A2 of the flat surface portion 111 when viewed from the Z direction. That is, the plurality of electronic components 10T and the base member 41T included in the subunit SUT face the second region A2 of the flat surface portion 111 in the Z direction.

### 8.2 Insulating Cover

The insulating cover 119 is a member for preventing a user's finger from contacting the energization path of the subunit SU. The insulating cover 119 is made of, for example, a synthetic resin and has an insulating property. The insulating cover 119 has, for example, a box shape that is open on the −Z direction side. The insulating cover 119 has a plurality of vent holes 119h. The insulating cover 119 covers a part or the whole of the corresponding subunit SU. Note that the insulating cover 119 is not limited to a box-shaped member, and may be a sheet-shaped member that covers the energization path of the main body MU. Further, the insulating cover 119 may be omitted.

### 9. Heat Transfer Portion

Next, the heat transfer member 120A will be described. The heat transfer member 120A is a member that causes heat to move from the first region R1 toward the second region R2 of the electrical connection unit 1 described above. The heat transfer member 120A is an example of a “heat transfer portion”. In the present embodiment, the heat transfer member 120A is formed separately from the metal plate 110.

As illustrated in FIG. 2, the plurality of heat transfer members 120A are disposed to be arranged at intervals in the X direction. Each of the plurality of heat transfer members 120A extends in the Y direction. The heat transfer member 120A extends over the first region A1 and the second region A2 of the metal plate 110 when viewed from the Z direction. The heat transfer member 120A includes, for example, a first portion 131, a second portion 132, and a third portion 133.

The first portion 131 forms, for example, the first end 130e1 (see FIG. 2) of the heat transfer member 120A. The first end 130e1 is, for example, the end of the heat transfer member 120A on the −Y direction side. The first portion 131 (for example, the first end 130e1) faces the first region A1 of the metal plate 110 when viewed from the Z direction.

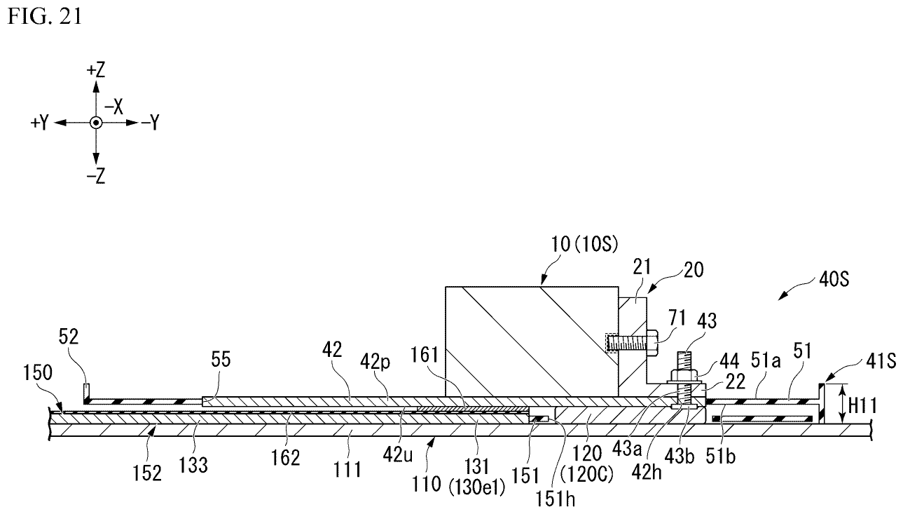

In the present embodiment, the first portion 131 (for example, the first end 130e1) is located between the first region A1 of the metal plate 110 and the base plate 41S of the subunit SUS in the Z direction (see FIG. 8). In the present embodiment, the first portion 131 (for example, the first end 130e1) is disposed between the bus bar 42 of the subunit SUS and the flat surface portion 111 of the metal plate 110, and is in contact with the connection portion 61 or the connection portion 62 of the bus bar 42 of the subunit SUS. The first portion 131 (for example, the first end 130e1) is thermally connected to the connection portion 61 or the connection portion 62 of the bus bar 42 of the subunit SUS. For example, the first portion 131 is thermally connected to the terminal 13 of the electronic component 10S via the connection portion 61 or the connection portion 62 of the bus bar 42 of the subunit SUS. In the present disclosure, the phrase “being in contact” is not limited to a case of being in direct contact, and may include a case of being connected via a member for securing an insulating property, such as an insulating sheet. For example, a case where the first portion 131 is in contact with the bus bar 42 may include a case where an insulating sheet (for example, an insulating sheet 162; and see FIG. 21) exists between the first portion 131 and the bus bar 42.

In the present embodiment, the first portion 131 (for example, the first end 130e1) is in contact with the first region A1 of the flat surface portion 111 of the metal plate 110. The first portion 131 (for example, the first end 130e1) is thermally connected to the first region A1 of the flat surface portion 111 of the metal plate 110.

The second portion 132 forms, for example, the second end 130e2 (see FIG. 2) of the heat transfer member 120A. The second end 130e2 is an end located on the side opposite to the first end 130e1. The second end 130e2 is, for example, the end of the heat transfer member 120A on the +Y direction side. The second portion 132 (for example, the second end 130e2) faces the second region A2 of the metal plate 110 when viewed from the Z direction.

In the present embodiment, the second portion 132 (for example, the second end 130e2) is located between the second region A2 of the metal plate 110 and the base member 41T of the subunit SUT in the Z direction (see FIGS. 14 and 15). The second portion 132 (for example, the second end 130e2) is in contact with the second region A2 of the flat surface portion 111 of the metal plate 110, and is thermally connected to the second region A2 of the flat surface portion 111 of the metal plate 110. The second portion 132 being in contact with the flat surface portion 111 of the metal plate 110 may include a case where an insulating sheet (for example, an insulating sheet 162; and see FIG. 21) exists between the second portion 132 and the flat surface portion 111 of the metal plate 110.

The third portion 133 is provided between the first portion 131 and the second portion 132 and extends in the Y direction. The third portion 133 couples the first portion 131 and the second portion 132. A part of the third portion 133 faces the first region A1 of the metal plate 110 when viewed from the Z direction. Another part of the third portion 133 faces the second region A2 of the metal plate 110 when viewed from the Z direction.

In the present embodiment, a part of the third portion 133 is located between the first region A1 of the metal plate 110 and the base plate 41S of the subunit SUS in the Z direction (see FIG. 8). In the present embodiment, the third portion 133 is disposed between the extending portion 63 or the connection portion 62 of the bus bar 42 of the subunit SUS and the flat surface portion 111 of the metal plate 110, and is in contact with the extending portion 63 or the connection portion 62 of the bus bar 42 of the subunit SUS. The third portion 133 is thermally connected to the extending portion 63 or the connection portion 62 of the bus bar 42. For example, the third portion 133 being in contact with the bus bar 42 may include a case where an insulating sheet (for example, an insulating sheet 162; and see FIG. 21) exists between the third portion 133 and the bus bar 42.

In the present embodiment, another part of the third portion 133 is located between the second region A2 of the metal plate 110 and the base member 41T of the subunit SUT in the Z direction (see FIG. 15). The third portion 133 is in contact with the second region A2 of the flat surface portion 111 of the metal plate 110, and is thermally connected to the second region A2 of the flat surface portion 111 of the metal plate 110. The third portion 133 being in contact with the flat surface portion 111 of the metal plate 110 may include a case where an insulating sheet (for example, an insulating sheet 162; and see FIG. 21) exists between the third portion 133 and the flat surface portion 111 of the metal plate 110.

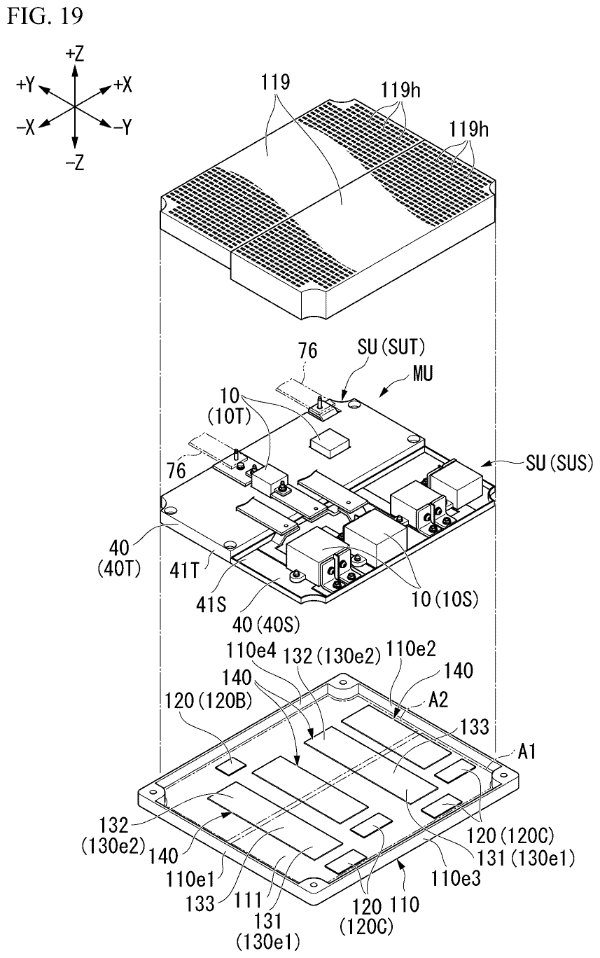

When another heat transfer member 120 (for example, a heat transfer member 120C illustrated in FIG. 19) that thermally connects the connection portion 61 of the bus bar 42 of the subunit SUS to the first region A1 of the metal plate 110 is provided, the heat transfer member 120A may be provided separately from the heat transfer member 120 (heat transfer member 120C). In this case, the first portion 131 (for example, the first end 130e1) of the heat transfer member 120A may be disposed between the extending portion 63 or the connection portion 62 of the bus bar 42 of the subunit SUS and the flat surface portion 111 of the metal plate 110, and may be in contact with the extending portion 63 or the connection portion 62 of the bus bar 42.

In a case where the electronic component 10S generates heat in the subunit SUS, part of the heat generated in the electronic component 10S is transmitted to the first region A1 of the flat surface portion 111 of the metal plate 110 through the first end 130e1 of the heat transfer member 120A, for example. The heat transferred to the first region A1 is dissipated from the first region A1 to the outside. In the present embodiment, another part of the heat generated in the electronic component 10S is transferred from the first region R1 to the second region R2 of the electrical connection unit 1 through, for example, the heat transfer member 120A, and is transferred to the second region A2 of the flat surface portion 111 of the metal plate 110. The heat transferred to the second region A2 is dissipated from the second region A2 to the outside. That is, in addition to the first region A1 of the metal plate 110, the second region A2 also contributes to heat dissipation of the electronic component 10S.

### 10. Advantages

As a comparative example, a constitution in which the heat transfer member 120A is not present and the heat transfer member 120 (for example, the heat transfer member 120C illustrated in FIG. 19) that thermally connects the connection portion 61 of the bus bar 42 of the subunit SUS to the first region A1 of the metal plate 110 is provided will be considered. In the constitution of the comparative example, the first region A1 of the metal plate 110 is effectively used as a region for releasing heat of the subunit SUS in which a heat dissipation property is emphasized. On the other hand, the second region A2 of the metal plate 110 is likely to have a lower temperature than the first region A1, and may not be effectively used as a region for releasing heat. In this case, there is room for improvement in the heat dissipation property of the electrical connection unit.

On the other hand, in the present embodiment, the electrical connection unit 1 includes a heat dissipation member (for example, the metal plate 110), a first electronic component (for example, the electronic component 10S), a first base member (for example, the base plate 41S), a first bus bar (for example, the bus bar 42 of the subunit SUS), a second electronic component (for example, the electronic component 10T), a second base member (for example, the base member 41T), and a heat transfer portion (for example, the heat transfer member 120A). The heat dissipation member includes a first region (for example, the first region A1) and a second region (for example, the second region A2). The first electronic component faces the first region in a first direction. The first base member faces the first region in the first direction and has an insulating property. The first bus bar is supported by the first base member and electrically connected to the first electronic component. The second electronic component faces the second region in the first direction. The second electronic component has a smaller amount of heat generation than the first electronic component. The second base member faces the second region in the first direction and has an insulating property. The second bus bar is supported by the second base member and electrically connected to the second electronic component. The heat transfer portion extends over the first region and the second region when viewed from the first direction.

According to such a constitution, at least part of heat generated in the first electronic component can be caused to move to the second region of the heat dissipation member by the heat transfer portion. As a result, the second region of the heat dissipation member can be effectively used as a region for releasing at least part of heat generated in the first electronic component. Through this operation, the heat dissipation property of the electrical connection unit 1 can be improved.

In the present embodiment, the first base member includes a flat surface portion (for example, the flat surface portion 51). The first bus bar is supported by the flat surface portion. The second base member has a three-dimensional structure thicker in the first direction than the first base member. According to such a constitution, it is possible to promote heat dissipation of the electronic component 10S having a great amount of heat generation by using the region where the second base member having a relatively thick three-dimensional structure is disposed (for example, the region where the electronic component 10T requiring a complicated execution structure is disposed). Through this operation, the heat dissipation property of the electrical connection unit 1 can be further improved.

In the present embodiment, the heat transfer portion includes a first portion (for example, the first portion 131) and a second portion (for example, the second portion 132). The first portion is located between the first region and the first base member in the first direction. The second portion is located between the second region and the second base member in the first direction. According to such a constitution, the heat transfer portion can be provided by using the gap between the first base member and the heat dissipation member and the gap between the second base member and the heat dissipation member. According to this constitution, even in a case where the heat transfer portion is provided, the electrical connection unit 1 can be easily miniaturized.

In the present embodiment, the heat transfer portion is a heat transfer member formed separately from the heat dissipation member. According to such a constitution, the degree of freedom of the shape and disposition layout of the heat transfer portion is easily increased. With this constitution, it is possible to further improve the heat dissipation property of the electrical connection unit 1 and/or to further miniaturize the electrical connection unit 1.

### 11. Modification Examples

Next, several modification examples of the embodiment will be described. Note that a constitution other than that described below in each modification example is the same as the constitution of the above-described embodiment.

### 11.1 Modification Examples Related to Heat Transfer Portion

### First Modification Example

FIG. 19 is a perspective view for describing an electrical connection unit 1 of a first modification example. In the present modification example, the electrical connection unit 1 includes a heat transfer member 120C and a heat transfer portion 140 instead of the heat transfer member 120A.

The heat transfer member 120C is a heat transfer member that transfers heat of the subunit SUS to the first region A1 of the flat surface portion 111 of the metal plate 110. The heat transfer member 120C is an example of the heat transfer member 120 described above. The heat transfer member 120C is disposed at a position overlapping a part of the bus bar 42 of the subunit SUS when viewed from the Z direction. The heat transfer member 120C is disposed between the bus bar 42 of the subunit SUS and the flat surface portion 111 of the metal plate 110. In the present embodiment, the heat transfer member 120C is disposed between the exposed portion 42u of the bus bar 42 and the first region A1 of the flat surface portion 111 of the metal plate 110, and is in contact with each of the exposed portion 42u of the bus bar 42 and the first region A1 of the flat surface portion 111 of the metal plate 110. The heat transfer member 120C transfers heat transferred from the electronic component 10 (for example, the electronic component 10S) to the bus bar 42 and/or heat generated by the bus bar 42, from the bus bar 42 to the first region A1 of the flat surface portion 111 of the metal plate 110.

In the present modification example, the heat transfer member 120C is disposed at a position overlapping a part of the bus bar 42 of the subunit SUS in the vicinity of the electronic component 10 (for example, the electronic component 10S) when viewed from the Z direction. In the present embodiment, the heat transfer member 120C is disposed at a position overlapping the connection component 20 when viewed from the Z direction. In other words, the heat transfer member 120C is disposed at a position overlapping the connection portion 61 or the connection portion 62 of the bus bar 42 when viewed from the Z direction. The heat transfer member 120C transfers heat moving from the electronic component 10S to the bus bar 42 of the subunit SUS via the connection component 20, from the bus bar 42 of the subunit SUS to the first region A1 of the flat surface portion 111 of the metal plate 110.

The heat transfer portion 140 is a heat transfer portion that is provided separately from the heat transfer member 120C and causes heat to move from the first region R1 toward the second region R2 of the electrical connection unit 1. The heat transfer portion 140 is made of metal (for example, made of copper, made of a copper alloy, made of aluminum, or made of an aluminum alloy). The heat transfer portion 140 has higher thermal conductivity than, for example, the base plate 41S (or the base member 41T). In the present embodiment, the heat transfer portion 140 is a thick portion of the metal plate 110 provided as a part of the metal plate 110. That is, the heat transfer portion 140 is a protruding portion protruding in the +Z direction from the flat surface portion 111 of the metal plate 110. Alternatively, the heat transfer portion 140 may be formed of a metal member separate from the metal plate 110.

As illustrated in FIG. 19, the plurality of heat transfer portions 140 are disposed to be arranged at intervals in the X direction. Each of the plurality of heat transfer portions 140 extends in the Y direction. The heat transfer portion 140 extends over the first region A1 and the second region A2 of the metal plate 110 when viewed from the Z direction. Similarly to the heat transfer member 120A described above, the heat transfer portion 140 includes, for example, a first portion 131, a second portion 132, and a third portion 133. Details of the heat transfer portion 140 are similar to the contents of the heat transfer member 120A described above. Thus, in the description of the heat transfer member 120A, the “heat transfer member 120A” may be replaced with the “heat transfer portion 140” in the description of the heat transfer member 140 other than the following description.

The first portion 131 forms, for example, a first end 130e1 of the heat transfer portion 140. The first end 130e1 is, for example, the end of the heat transfer portion 140 on the −Y direction side. The first portion 131 (for example, the first end 130e1) faces the first region A1 of the metal plate 110 when viewed from the Z direction. The first portion 131 is formed integrally with the first region A1 of the metal plate 110, for example.

In the present embodiment, the first portion 131 (for example, the first end 130e1) is located between the first region A1 of the metal plate 110 and the base plate 41S of the subunit SUS in the Z direction. In the present embodiment, the first portion 131 (for example, the first end 130e1) is disposed between the bus bar 42 of the subunit SUS and the flat surface portion 111 of the metal plate 110, and is in contact with the connection portion 61, the connection portion 62, or the extending portion 63 of the bus bar 42 of the subunit SUS. The first portion 131 (for example, the first end 130e1) is thermally connected to the connection portion 61, the connection portion 62, or the extending portion 63 of the bus bar 42 of the subunit SUS.

The second portion 132 forms, for example, the second end 130e2 of the heat transfer portion 140. The second end 130e2 is, for example, the end of the heat transfer portion 140 on the +Y direction side. The second portion 132 (for example, the second end 130e2) faces the second region A2 of the metal plate 110 when viewed from the Z direction. The second portion 132 is formed integrally with the second region A2 of the metal plate 110, for example.

In the present embodiment, the second portion 132 (for example, the second end 130e2) is located between the second region A2 of the metal plate 110 and the base member 41T of the subunit SUT in the Z direction. The second portion 132 (for example, the second end 130e2) is in contact with the second region A2 of the flat surface portion 111 of the metal plate 110, and is thermally connected to the second region A2 of the flat surface portion 111 of the metal plate 110.

The third portion 133 is provided between the first portion 131 and the second portion 132 and extends in the Y direction. The third portion 133 couples the first portion 131 and the second portion 132. A part of the third portion 133 faces the first region A1 of the metal plate 110 when viewed from the Z direction. Another part of the third portion 133 faces the second region A2 of the metal plate 110 when viewed from the Z direction.

In the present embodiment, a part of the third portion 133 is disposed between the extending portion 63 or the connection portion 62 of the bus bar 42 of the subunit SUS and the flat surface portion 111 of the metal plate 110, and is in contact with the extending portion 63 or the connection portion 62 of the bus bar 42. A part of the third portion 133 is formed integrally with the first region A1 of the metal plate 110, for example.

Another part of the third portion 133 is in contact with the second region A2 of the flat surface portion 111 of the metal plate 110, and is thermally connected to the second region A2 of the flat surface portion 111 of the metal plate 110. The another part of the third portion 133 is formed integrally with the second region A2 of the metal plate 110, for example.

According to such a constitution, the heat transfer portion 140 made of metal can promote the movement of heat from the first region R1 toward the second region R2 of the electrical connection unit 1. With this constitution, it is possible to further improve the heat dissipation property of the electrical connection unit 1. In the present embodiment, the heat transfer portion 140 is made of metal. In this case, the heat transfer portion 140 having a high thermal conductivity can further promote the movement of heat.

### Second Modification Example

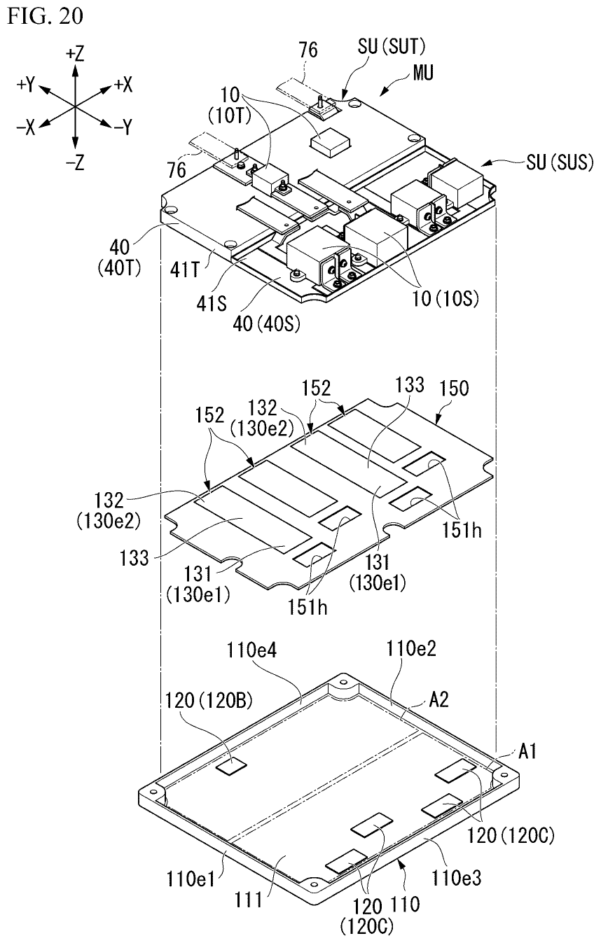

FIG. 20 is a perspective view for describing an electrical connection unit 1 of a second modification example. In the present modification example, the electrical connection unit 1 includes a heat transfer member 120C, a heat transfer board 150, a heat transfer member 120D, a heat transfer material 161 (see FIG. 23), and an insulating sheet 162 (see FIG. 23). Note that the contents of the heat transfer member 120C are the same as those described in the first modification example, and thus repeated description will be omitted.

The heat transfer board 150 is a board-type heat transfer portion that causes heat to move from the first region R1 toward the second region R2 of the electrical connection unit 1. The heat transfer board 150 is disposed between the above-described two subunits SU (subunits SUS and SUT) and the flat surface portion 111 of the metal plate 110 in the Z direction. The heat transfer board 150 includes a base plate 151 and one or more (for example, a plurality of) heat transfer bus bars 152.

In the present embodiment, the base plate 151 and the plurality of bus bars 152 are integrated through insert molding. For example, the heat transfer board 150 is formed as one piece member by insert-molding the bus bar 152 with the base plate 151. That is, the bus bar 152 is integrated with the base plate 151 without using a fastening member such as a screw or a bolt. Similarly to the routing board 40, the heat transfer board 150 may be formed by using another structure instead of the insert molding.

The base plate 151 is a support member that integrally supports the plurality of bus bars 152 arranged at intervals in the horizontal direction. The base plate 151 is made of, for example, a synthetic resin and has an insulating property. The base plate 151 has, for example, a plate shape formed in the horizontal direction. The base plate 151 is an example of a “base member”. The base plate 151 may be referred to as an “insulating substrate”.

The base plate 151 has, for example, one or more (for example, a plurality of) accommodation portions 155 in which the bus bars 152 are accommodated, respectively. The plurality of accommodation portions 155 are formed apart from each other in the X direction or the Y direction. Each of the accommodation portions 155 is, for example, a through-hole penetrating the base plate 151 in the Z direction. Note that the accommodation portion 155 may be a recess provided in the surface of the base plate 151 and recessed in the Z direction instead of the through-hole. Each accommodation portion 155 has an outer shape corresponding to the shape of the bus bar 152 to be accommodated when viewed from the Z direction. The base plate 151 has an opening 151h for avoiding interference with the heat transfer member 120C.

The bus bar 152 for heat transfer is a bus bar that causes heat to move from the first region R1 toward the second region R2 of the electrical connection unit 1. The bus bar 152 is made of metal (for example, made of copper, made of a copper alloy, made of aluminum, or made of an aluminum alloy). The bus bar 152 has, for example, a higher thermal conductivity than the base plate 41S. The bus bar 152 is an example of a “heat transfer portion”. The bus bar 152 may be referred to as a “metal member”.

As illustrated in FIG. 20, the plurality of bus bars 152 are disposed to be arranged at intervals in the X direction. Each of the plurality of bus bars 152 extends in the Y direction. The bus bar 152 extends over the first region A1 and the second region A2 of the metal plate 110 when viewed from the Z direction. The bus bar 152 includes, for example, a first portion 131, a second portion 132, and a third portion 133. Details of the bus bar 152 are similar to the contents of the heat transfer member 120A or the heat transfer portion 140 described above. Therefore, in the description of the heat transfer member 120A or the heat transfer portion 140, the “heat transfer member 120A” or the “heat transfer portion 140” may be replaced with the “bus bar 152” in the description of the bus bar 152.

FIG. 21 is a cross-sectional view for describing the electrical connection unit 1 of the second modification example. In the present modification example, the bus bar 152 is made of metal and has a rigidity. The first portion 131 (for example, the first end 130e1) of the bus bar 152 faces the bus bar 42 of the subunit SUS in the Z direction. The first portion 131 (for example, the first end 130e1) of the bus bar 152 is thermally connected to the bus bar 42 of the subunit SUS.

In the present modification example, the heat transfer material 161 is provided between the first portion 131 (for example, the first end 130e1) of the bus bar 152 and the bus bar 42. The heat transfer material 161 is a heat transfer material for thermally connecting the bus bar 152 to the bus bar 42 more firmly. The heat transfer material 161 is, for example, heat transfer grease, but may be a heat transfer sheet or the like having an elasticity. The heat transfer material 161 has, for example, a higher thermal conductivity than the base plate 41S (or the base member 41T).

In the present modification example, the insulating sheet 162 is provided between the first portion 131 (for example, the first end 130e1) of the bus bar 152 and the bus bar 42. The bus bar 152 and the bus bar 42 are electrically insulated by the insulating sheet 162.

In the present modification example, the heat transfer member 120D (see FIG. 22) is provided between the second portion 132 (for example, the second end 130e2) of the bus bar 152 and the second region A2 of the flat surface portion 111 of the metal plate 110. The heat transfer member 120D is an example of the heat transfer member 120 described above. The second portion 132 of the bus bar 152 is thermally connected to the second region A2 of the flat surface portion 111 of the metal plate 110 via the heat transfer member 120D.

According to such a constitution, the bus bar 152 for heat transfer can promote the transfer of heat from the first region R1 toward the second region R2 of the electrical connection unit 1. With this constitution, the heat dissipation property of the electrical connection unit 1 can be further improved.

### 11.2 Modification Examples Related to Routing Board

### First Modification Example

The routing board 40S is not limited to a structure in which the base plate 41S and the bus bar 42 are integrated through insert molding. For example, the bus bar 42 may be disposed in the accommodation portion 55 after the base plate 41S provided with the accommodation portion 55 accommodating the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

### Second Modification Example

The base member of the routing board 40S is not limited to the base plate 41S having the plate-shaped flat surface portion 51. The routing board 40S may be a base member (for example, an insulating sheet) having a sheet-shaped flat surface portion 51. In this case, the accommodation portion 55 may be formed by a part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### Third Modification Example

The base plate 41S of the routing board 40S may include a plurality of members (plate members or sheet members). The plurality of members are provided to sandwich the plurality of bus bars 42 arranged in the horizontal direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41S (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed.

### Fourth Modification Example

A connection between the electronic component 10 and the bus bar 42 is not limited to the connection using the connection component 20. The electronic component 10 may be directly connected to the bus bar 42 by using a fastening member (for example, a bolt or a screw), welding, or the like.

Several embodiments and modification examples have been described above. However, the embodiment and the modification examples are not limited to the examples described above. For example, the plurality of modification examples described above may be implemented in combination with each other.

### DESCRIPTION OF REFERENCE SYMBOLS

1 Electrical connection unit
SU, SUS, SUT Subunit
10, 10S, 10T, 10TA, 10TB Electronic component
13, 13A, 13B Terminal
20 Connection component
40S Routing board
40T Routing structure
41S Base plate
41T Base member
42 Bus bar
51 Flat surface portion
52 Frame portion
55 Accommodation portion
61 Connection portion
62 Connection portion
63 Extending portion
84A, 84B Accommodation portion
85 Frame portion
110 Metal plate (heat dissipation member, rigid member, metal member)
111 Flat surface portion (facing portion)
120 Heat transfer member
120A Heat transfer member (heat transfer portion)
120B, C Heat transfer member
131 First portion
132 Second portion
133 Third portion
140 Heat transfer portion
150 Heat transfer board
151 Base plate
152 Bus bar for heat transfer
161 Heat transfer material

1. An electrical connection unit comprising:
a heat dissipation member including a first region and a second region;
a first electronic component facing the first region in a first direction;
an insulating first base member facing the first region in the first direction;
a first bus bar supported by the first base member and electrically connected to the first electronic component;
a second electronic component facing the second region in the first direction and having a smaller amount of heat generation than the first electronic component;
an insulating second base member facing the second region in the first direction;
a second bus bar supported by the second base member and electrically connected to the second electronic component; and
a heat transfer portion extending over the first region and the second region when viewed from the first direction.

2. The electrical connection unit according to claim 1, wherein
the first base member includes a flat surface portion,
the first bus bar is supported by the flat surface portion, and
the second base member has a three-dimensional structure thicker in the first direction than the first base member.

3. The electrical connection unit according to claim 1, wherein the heat transfer portion includes a first portion and a second portion, and the first portion is located between the first region and the first base member in the first direction, and the second portion is located between the second region and the second base member in the first direction.

4. The electrical connection unit according to claim 1, further comprising a heat transfer material disposed between the first bus bar and the heat transfer portion.

5. The electrical connection unit according to claim 1, wherein the heat transfer portion is a heat transfer member formed separately from the heat dissipation member.

6. The electrical connection unit according to claim 1, wherein the heat dissipation member is made of metal, and the heat transfer portion is a thick portion of the heat dissipation member provided as a part of the heat dissipation member.
